(19) United States
(12) Patent Application Publication
(10) Pub. No.: US 2026/0271456 A1
(43) Pub. Date: Sep. 10, 2026

(54) DISPLAY DEVICE, MANUFACTURING METHOD OF THE SAME AND ELECTRONIC DEVICE

(71) Applicant: Samsung Display Co., Ltd., Yongin-si (KR)

(72) Inventors: Min Sik JUNG, Yongin-si (KR); Min Hyuck PARK, Yongin-si (KR); Jae Phil LEE, Yongin-si (KR); Hoon LEE, Yongin-si (KR); Jae Chil HWANG, Yongin-si (KR)

(21) Appl. No.: 19/431,839

(22) Filed: Dec. 23, 2025

(30) Foreign Application Priority Data
Mar. 5, 2025 (KR) 10-2025-0028181
May 15, 2025 (KR) 10-2025-0063049

(51) Int. Cl. H10H 29/49; H10H 29/01; H10H 29/03

(52) U.S. Cl. CPC H10H 29/49; H10H 29/012; H10H 29/03

(57) ABSTRACT

A display device includes: a substrate; a pixel electrode and a common electrode spaced from each other on the substrate; a first organic layer covering at least a portion of the pixel electrode and the common electrode; and a light emitting element on the first organic layer, the light emitting element including a plurality of semiconductor layers, a first contact electrode, and a second contact electrode, wherein the first contact electrode and the second contact electrode are respectively located on one surface and a side surface of the light emitting element, and are spaced from a top surface of the light emitting element, and wherein 10% or more and 60% or less of the first contact electrode and the second contact electrode located on the side surface of the light emitting element are embedded in the first organic layer.

### CROSS-REFERENCE TO RELATED APPLICATIONS

The present application claims priority to and the benefit of Korean Patent Application No. 10-2025-0028181, filed on Mar. 05, 2025, and Korean Patent Application No. 10-2025-0063049, filed on May 15, 2025, in the Korean Intellectual Property Office, the entire disclosures of which are incorporated by reference herein.

### BACKGROUND

### 1. Field

The present disclosure relates to a display device, a method of manufacturing the same, and an electronic device.

### 2. Description of the Related Art

With the development of the information society, the demand for display devices for displaying images is increasing in various forms. The display device may be a flat panel display such as a liquid crystal display, a field emission display, a light emitting display, and/or the like.

The light emitting display device may be implemented as an organic light emitting display device including an organic light emitting diode (OLED) element as the light emitting element, an inorganic light emitting display device including an inorganic semiconductor element as the light emitting element, or a ultra-small light emitting diode display device including a ultra-small light emitting diode element (or micro light emitting diode element) as the light emitting element.

### SUMMARY

Aspects and features of embodiments of the present disclosure are to provide a display device, and a method of manufacturing the same that can reduce or minimize the disconnection of the connecting electrodes of the light-emitting element.

However, aspects and features of embodiments of the present disclosure are not restricted to the one set forth herein. The above and other aspects and features of embodiments of the present disclosure will become more apparent to one of ordinary skill in the art to which the present disclosure pertains by referencing the detailed description of the present disclosure given below.

According to one or more embodiments of the present disclosure, a display device includes: a substrate; a pixel electrode and a common electrode spaced from each other on the substrate; a first organic layer covering at least a portion of the pixel electrode and the common electrode; and a light emitting element on the first organic layer, the light emitting element including a plurality of semiconductor layers, a first contact electrode, and a second contact electrode, wherein the first contact electrode and the second contact electrode are respectively located on one surface and a side surface of the light emitting element, and are spaced from a top surface of the light emitting element, and wherein 10% or more and 60% or less of the first contact electrode and the second contact electrode located on the side surface of the light emitting element are embedded in the first organic layer.

In one or more embodiments, the first organic layer covers 5% or more and 30% or less of the side surface of the light emitting element.

In one or more embodiments, each of a height of the first contact electrode and the second contact electrode located on the side surface of the light emitting element is 50% of the height of the light emitting element.

In one or more embodiments, the first organic layer is on an entire surface of the substrate and covers the side surface of the light emitting element.

In one or more embodiments, the first organic layer covers the pixel electrode and the common electrode and includes a first connection hole exposing a portion of the pixel electrode, a second connection hole exposing a portion of the common electrode, and wherein the display device further includes a first connection electrode and a second connection electrode, the first connection electrode connecting the pixel electrode and the first contact electrode through the first connection hole, and the second connection electrode connecting the common electrode and the second contact electrode through the second connection hole.

In one or more embodiments, the first contact electrode is in direct contact with the first connection electrode at a side of the plurality of semiconductor layers, and wherein the second contact electrode is in direct contact with the second connection electrode at the side of the plurality of semiconductor layers.

In one or more embodiments, a groove formed by a thickness of the first contact electrode and the second contact electrode is on one side of the light emitting element, and wherein the groove is filled with the first organic layer.

In one or more embodiments, the light emitting element further includes: a conductive layer on one surface of the plurality of semiconductor layers; and a protective film on one surface and side surfaces of the conductive layer and side surfaces of the plurality of semiconductor layers, wherein the first contact electrode is on the protective film and is connected to the conductive layer exposed without being covered by the protective film, and wherein the second contact electrode is on the protective film and is in a hole penetrating the conductive layer and a portion of the plurality of semiconductor layers.

In one or more embodiments, the hole is filled with the first organic layer.

In one or more embodiments, a method for manufacturing a display device includes: forming light emitting elements, a light emitting element of the light emitting elements including a plurality of semiconductor layers on a semiconductor substrate; forming a protective layer of the light emitting element and a first contact electrode and a second contact electrode covering one side and a side surface of the light emitting element; transferring the light emitting element onto a first organic layer coated on an entire surface of a circuit substrate covering a pixel electrode and a common electrode on the circuit substrate; and forming a first connection electrode connecting the pixel electrode and the first contact electrode and a second connection electrode connecting the common electrode and the second contact electrode by a photo process, wherein 10% or more and 60% or less of the first contact electrode and the second contact electrode on the side surface of the light emitting element are embedded in the first organic layer.

In one or more embodiments, the first organic layer covers 5% or more and 30% or less of the side surface of the light emitting element.

In one or more embodiments, the forming the protective layer of the light emitting element and the first contact electrode and the second contact electrode covering the one side and the side surface of the light emitting element includes: forming a protective material layer around each of the light emitting elements and patterning the protective material layer to form a protective film; forming an insulating layer on the protective film covering 50% of height of the light emitting element and forming a contact electrode layer; and removing the insulating layer to form the first contact electrode and the second contact electrode in each of the light emitting elements, wherein heights of the first contact electrode and the second contact electrode are 50% of the height of the light emitting element.

In one or more embodiments, the method further includes: forming a first connection hole in the first organic layer exposing a portion of the pixel electrode and a second connection hole exposing a portion of the common electrode, wherein the first connection electrode connects the pixel electrode and the first contact electrode through the first connection hole, and wherein the second connection electrode connects the common electrode and the second contact electrode through the second connection hole.

In one or more embodiments, the first connection electrode is connected to a portion of the first contact electrode that is not embedded in the first organic layer, and wherein the second connection electrode is connected to a portion of the second contact electrode that is not embedded in the first organic layer.

In one or more embodiments, the forming the light emitting elements including the plurality of semiconductor layers on the semiconductor substrate further includes: forming a second semiconductor material layer, an active material layer, a first semiconductor material layer, and a conductive material layer on the semiconductor substrate; etching the second semiconductor material layer, the active material layer, the first semiconductor material layer, and the conductive material layer to form light emitting elements including a second semiconductor layer, an active layer, a first semiconductor layer, and a conductive layer, respectively; and forming a hole penetrating the conductive layer, the first semiconductor layer, and the active layer in each of the light emitting elements, wherein the first contact electrode is connected to the conductive layer, and the second contact electrode is connected to the second semiconductor layer in the hole.

In one or more embodiments, the hole is filled with the first organic layer.

In one or more embodiments, a groove formed by a thickness of the first contact electrode and the second contact electrode is formed on one side of the light emitting element, and wherein the groove is filled with the first organic layer.

In one or more embodiments, the first organic layer is controlled by lowering a content of a photoinitiator in the first organic layer or increasing a content of a fluidic monomer so that the first organic layer covers 10% or more and 60% or less of the first contact electrode and the second contact electrode located on side of the light emitting element.

In one or more embodiments, an electronic device includes: a display panel; a window on the display panel; and a bottom cover located below the display panel, wherein the display panel includes: a substrate; a pixel electrode and a common electrode spaced from each other on the substrate; a first organic layer covering at least a portion of the pixel electrode and the common electrode; and a light emitting element on the first organic layer, the light emitting element including a plurality of semiconductor layers, a first contact electrode, and a second contact electrode, wherein the first contact electrode and the second contact electrode are respectively located on one surface and a side surface of the light emitting element, and are spaced from a top surface of the light emitting element, and wherein the first organic layer covers 10% or more and 60% or less of the first contact electrode and the second contact electrode located on the side surface of the light emitting element.

In one or more embodiments, the electronic device further includes a battery located in a space of the bottom cover and configured to supply power to the electronic device; and a middle frame located between the window and the bottom cover.

In a display device and a manufacturing method thereof according to one or more embodiments, it is possible to reduce or minimize the disconnection of the connection electrode connecting the light emitting element, the pixel electrode, and the common electrode. Accordingly, the possibility of causing a dark spot when the display panel is turned on may be reduced, and the reliability of the panel may be improved.

However, the present disclosure is not limited to the aforementioned effects, aspects, and features, and various other effects, aspects, and features are included in the present specification.

### BRIEF DESCRIPTION OF THE DRAWINGS

FIG. 1 is a perspective view illustrating a display device according to one or more embodiments.

FIG. 2 is a layout diagram illustrating a display device according to one or more embodiments.

FIG. 3 is a block diagram illustrating a display device according to one or more embodiments.

FIG. 4 is an equivalent circuit diagram illustrating a sub-pixel according to one or more embodiments.

FIG. 5 is a layout diagram illustrating pixels of a display area according to one or more embodiments.

FIG. 6 is a cross-sectional view illustrating an example cross-section of one display panel corresponding to the lines I-I' in FIG. 5.

FIG. 7 is a cross-sectional view illustrating an example of an area A in FIG. 6 in detail.

FIG. 8 is a flow chart illustrating a method for manufacturing a display device according to one or more embodiments.

FIGS. 9 - 18 are example drawings to illustrate a method for manufacturing a display device according to one or more embodiments.

FIG. 19 is a perspective view to illustrate an air gap (or air pocket) according to a bonding state of a conventional light emitting element and a first organic layer.

FIG. 20 is a graph to illustrate a bonding characteristic according to a process of the first organic layer according to one or more embodiments.

FIGS. 21 and 22 are example drawings illustrating a smart watch including a display device according to one or more embodiments.

FIG. 23 is an exploded perspective view of a smart watch including a display device according to one or more embodiments.

FIGS. 24 is an example views of a virtual reality (VR) device including a display device according to one or more embodiments.

FIG. 25 is an example view of a VR device including a display device according to one or more embodiments.

FIG. 26 is an example view illustrating a vehicle instrument cluster and center fascia including display devices according to one or more embodiments.

FIG. 27 is an example view of a transparent display device including a display device according to one or more embodiments.

### DETAILED DESCRIPTION

Aspects and features of embodiments of the present disclosure and methods of accomplishing the same may be understood more readily by reference to the detailed description of embodiments and the accompanying drawings. Hereinafter, aspects of some embodiments will be described in more detail with reference to the accompanying drawings. The described embodiments, however, may be embodied in various different forms, and should not be construed as being limited to only the illustrated embodiments herein. Rather, these embodiments are provided as examples so that the present disclosure will be thorough and complete, and will fully convey the aspects and features of the present disclosure to those skilled in the art. Accordingly, processes, elements, and techniques that are not necessary to those having ordinary skill in the art for a complete understanding of the aspects and features of the present disclosure might not be described.

Unless otherwise noted, like reference numerals, characters, or combinations thereof denote like elements throughout the attached drawings and the written description, and thus, descriptions thereof will not be repeated. Further, parts not related to the description of one or more embodiments might not be shown to make the description clear.

In the drawings, the relative sizes of elements, layers, and regions may be exaggerated for clarity. Additionally, the use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Various embodiments are described herein with reference to sectional illustrations that are schematic illustrations of embodiments and/or intermediate structures. As such, variations from the shapes of the illustrations as a result, for example, of manufacturing techniques and/or tolerances, are to be expected. Further, specific structural or functional descriptions disclosed herein are merely illustrative for the purpose of describing embodiments according to the present disclosure. Thus, embodiments disclosed herein should not be construed as limited to the particular illustrated shapes of regions, but are to include deviations in shapes that result from, for instance, manufacturing.

For example, an implanted region illustrated as a rectangle may have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the drawings are schematic in nature and their shapes are not intended to illustrate the actual shape of a region of a device and are not intended to be limiting. Additionally, as those skilled in the art would realize, the described embodiments may be modified in various different ways, all without departing from the spirit and/or scope of the present disclosure.

In the detailed description, for the purposes of explanation, numerous specific details are set forth to provide a thorough understanding of various embodiments. It is apparent, however, that various embodiments may be practiced without these specific details or with one or more equivalent arrangements. In other instances, well-known structures and devices are shown in block diagram form to avoid unnecessarily obscuring various embodiments.

Spatially relative terms, such as “beneath,” “below,” “lower,” “under,” “above,” “upper,” and/or the like, may be used herein for ease of explanation to describe one element or feature’s relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below” or “beneath” or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. Similarly, when a first part is described as being arranged “on” a second part, this indicates that the first part is arranged at an upper side or a lower side of the second part without the limitation to the upper side thereof on the basis of the gravity direction.

Further, in this specification, the phrase “on a plane,” or “in a plan view,” means viewing a target portion from the top, and the phrase “on a cross-section” means viewing a cross-section formed by vertically cutting a target portion from the side.

It will be understood that when an element, layer, region, or component is referred to as being “formed on,” “on,” “connected to,” or “coupled to” another element, layer, region, or component, it can be directly formed on, on, connected to, or coupled to the other element, layer, region, or component, or indirectly formed on, on, connected to, or coupled to the other element, layer, region, or component such that one or more intervening elements, layers, regions, or components may be present. For example, when a layer, region, or component is referred to as being “electrically connected” or “electrically coupled” to another layer, region, or component, it can be directly electrically connected or coupled to the other layer, region, and/or component or intervening layers, regions, or components may be present. However, “directly connected/directly coupled” refers to one component directly connecting or coupling another component without an intermediate component. Meanwhile, other expressions describing relationships between components such as “between,” “immediately between” or “adjacent to” and “directly adjacent to” may be construed similarly. In addition, it will also be understood that when an element or layer is referred to as being “between” two elements or layers, it can be the only element or layer between the two elements or layers, or one or more intervening elements or layers may also be present.

For the purposes of the present disclosure, expressions such as “at least one of,” “one of,” and “selected from,” when preceding a list of elements, modify the entire list of elements and do not modify the individual elements of the list. For example, “at least one of X, Y, and Z,” “at least one of X, Y, or Z,” and “at least one selected from the group consisting of X, Y, and Z” may be construed as X only, Y only, Z only, any combination of two or more of X, Y, and Z, such as, for instance, XYZ, XYY, XZ, YZ, and ZZ, or any variation thereof. Similarly, the expression such as “at least one of A and/or B” may include A, B, or A and B. As used herein, the term “and/or” includes any and all combinations of one or more of the associated listed items. For example, the expression such as “A and/or B” may include A, B, or A and B. Further, the use of “may” when describing embodiments of the disclosure refers to “one or more embodiments of the disclosure”.

It will be understood that, although terms “first,” “second,” “third,” etc., may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure.

In the examples, the x-axis, the y-axis, and/or the z-axis are not limited to three axes of a rectangular coordinate system, and may be interpreted in a broader sense. For example, the x-axis, the y-axis, and the z-axis may be perpendicular to one another, or may represent different directions that are not perpendicular to one another. The same applies for first, second, and/or third directions.

The terminology used herein is for the purpose of describing particular embodiments only and is not intended to be limiting of the present disclosure. As used herein, the singular forms “a” and “an” are intended to include the plural forms as well, unless the context clearly indicates otherwise. It will be further understood that the terms “comprises,” “comprising,” “have,” “having,” “includes,” and “including,” when used in this specification, specify the presence of the stated features, integers, steps, operations, elements, and/or components, but do not preclude the presence or addition of one or more other features, integers, steps, operations, elements, components, and/or groups thereof.

As used herein, the term “substantially,” “about,” “approximately,” and similar terms are used as terms of approximation and not as terms of degree, and are intended to account for the inherent deviations in measured or calculated values that would be recognized by those of ordinary skill in the art. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ± 30%, 20%, 10%, 5% of the stated value. Further, the use of “may” when describing embodiments of the present disclosure refers to “one or more embodiments of the disclosure.”

When one or more embodiments may be implemented differently, a specific process order may be performed differently from the described order. For example, two consecutively described processes may be performed substantially at the same time or performed in an order opposite to the described order.

Also, any numerical range disclosed and/or recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, for example, having a minimum value equal to or greater than 1.0 and a maximum value equal to or less than 10.0, such as, for example, 2.4 to 7.6. Any maximum numerical limitation recited herein is intended to include all lower numerical limitations subsumed therein, and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein. All such ranges are intended to be inherently described in this specification such that amending to expressly recite any such subranges would comply with the requirements of 35 U.S.C. § 112(a) and 35 U.S.C. § 132(a).

The electronic or electric devices and/or any other relevant devices or components according to one or more embodiments of the present disclosure described herein may be implemented utilizing any suitable hardware, firmware (e.g., an application-specific integrated circuit), software, or a combination of software, firmware, and hardware. For example, the various components of these devices may be formed on one integrated circuit (IC) chip or on separate IC chips. Further, the various components of these devices may be implemented on a flexible printed circuit film, a tape carrier package (TCP), a printed circuit board (PCB), or formed on one substrate.

Further, the various components of these devices may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, and/or the like. Also, a person of skill in the art should recognize that the functionality of various computing devices may be combined or integrated into a single computing device, or the functionality of a particular computing device may be distributed across one or more other computing devices without departing from the spirit and scope of the present disclosure.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning for example consistent with their meaning in the context of the relevant art and/or the present specification, and should not be interpreted in an idealized or overly formal sense, unless expressly so defined herein.

A person of ordinary skill in the art would appreciate, in view of the present disclosure in its entirety, that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

Hereinafter, embodiments of the present disclosure are described with reference to the drawings.

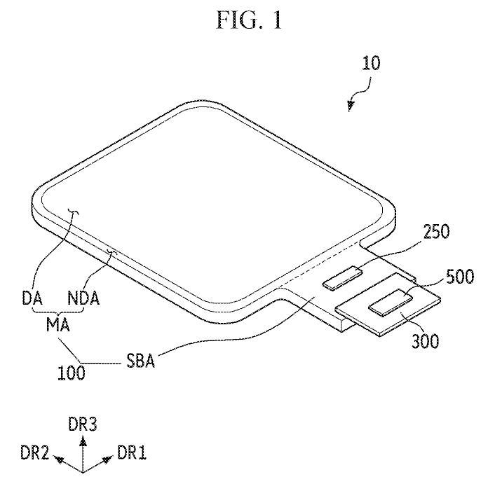

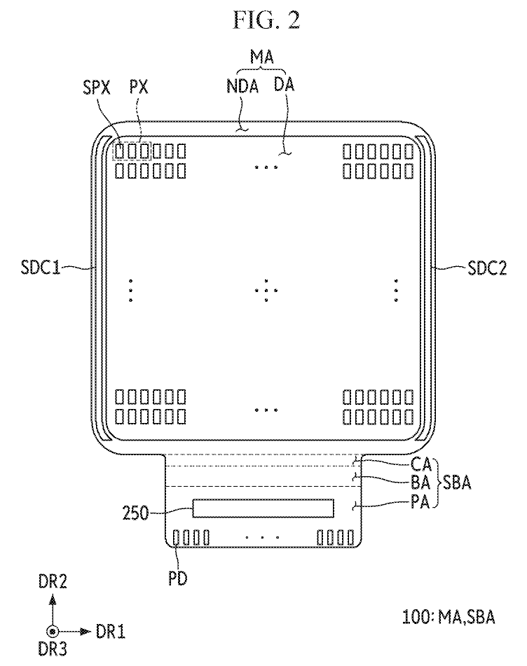

FIG. 1 is a schematic perspective view illustrating a display device according to one or more embodiments.

Referring to FIG. 1, a display device 10 may be for displaying video and/or still images, such as mobile phones, smart phones, tablet personal computers , and portable electronic devices such as smart watches, watch phones, mobile communication terminals, electronic notebooks, e-books, portable electronic devices such as portable multimedia players (PMP), navigation, and ultra mobile PC (UMPC), as well as display screens for a variety of products such as televisions, laptops, monitors, billboards, and/or the internet of things (IOT).

The display device 10 may be a light emitting display device, such as an organic light-emitting display device utilizing an organic light-emitting diode (OLED), a quantum dot light-emitting display device including a quantum dot light-emitting layer, an inorganic light-emitting display device including an inorganic semiconductor, and a miniaturized light-emitting display device utilizing a micro or nano light emitting diode (micro LED or nano LED). Hereinafter, the description focuses on the fact that the display device 10 is a micro-light emitting display device, but the disclosure is not limited thereto. On the other hand, hereinafter, an ultra-small light emitting diode is described as a light emitting element for convenience of explanation.

The display device 10 may include a display panel 100, a display driving circuit 250, a circuit substrate 300, and a power supply circuit 500.

The display panel 100 may be formed as a rectangular shaped plane having a short side in the first direction DR1 and a long side in the second direction DR2 that intersects the first direction DR1. A corner where the short side in the first direction DR1 and the long side in the second direction DR2 meet may be rounded to have a suitable curvature (e.g., a selected or predetermined curvature) or may be formed at a right angle. The planar shape of the display panel 100 is not limited to a rectangle, but may be formed in other polygonal, circular, or oval shapes. The display panel 100 may be formed flat but is not limited thereto. For example, the display panel 100 may be formed at the left and right ends and may include curved portions with a constant curvature or a changing curvature. The display panel 100 may be flexibly formed to be bent, curved, bent, folded, and/or rolled.

The substrate SUB of the display panel 100 may include a main area MA and a sub-area SBA.

The main area MA may include a display area DA that displays an image and a non-display area NDA that is a surrounding area of the display area DA. The display area DA may include multiple pixels that display an image. Each pixel may include multiple sub-pixels. For example, each of the pixels may include a first sub-pixel that emits light of a first color, a second sub-pixel that emits light of a second color, and a third sub-pixel that emits light of a third color. However, the present disclosure is not limited thereto.

The sub-area SBA may protrude from a side of the main area MA in the second direction DR2. Although FIG. 1 illustrates the sub-area SBA being unfolded, the sub-area SBA may be bent, and for example, may be disposed on the lower surface of the display panel 100. In case that the sub-area SBA is bent, it may overlap the main area MA in the third direction DR3, which is the thickness direction of the display panel 100. The display driving circuit 250 may be disposed in the sub-area SBA.

The display driving circuit 250 may generate signals and voltages for driving the display panel 100. The display driving circuit 250 may be formed as an integrated circuit (IC) and attached to the display panel 100 using a chip on glass (COG) method, a chip on plastic (COP) method, or an ultrasonic bonding method but is not limited thereto. The display driving circuit 250 may be attached to the circuit substrate 300 using a chip on film (COF) method.

The circuit substrate 300 may be attached to an end of the sub-area SBA of the display panel 100. For example, the circuit substrate 300 may be electrically connected to the display panel 100 and the display driving circuit 250. The display panel 100 and the display driving circuit 250 may receive digital video data, timing signals, and driving voltages through the circuit substrate 300. The circuit substrate 300 may be a flexible film, such as a flexible printed circuit substrate, a printed circuit substrate, or a chip on film.

The power supply circuit 500 may generate multiple panel driving voltages according to an external power supply voltage. The power supply circuit 500 may be formed as an integrated circuit (IC) and attached to the circuit substrate 300 using a COF method.

FIG. 2 is a schematic layout illustrating a display device according to one or more embodiments. FIG. 2 illustrates that the sub-area SBA is unfolded without being bent.

Referring to FIG. 2, the display panel 100 may include the main area MA and the sub-area SBA.

The main area MA may include the display area DA that displays an image and the non-display area NDA that is a peripheral area of the display area DA. The display area DA may occupy most of the main area MA. The display area DA may be disposed in the center of the main area MA.

The display area DA may include multiple pixels PX for displaying an image, and each of multiple pixels PX may include multiple sub-pixels SPX. A pixel PX may be defined as a sub-pixel group of the smallest unit capable of expressing a white grayscale level.

The non-display area NDA may be disposed adjacent to the display area DA. The non-display area NDA may be an area disposed outside the display area DA. The non-display area NDA may be arranged to be around (e.g., to surround) the display area DA. The non-display area NDA may be an edge area of the display panel 100.

A first scan driving portion SDC1 and a second scan driving portion SDC2 may be disposed in the non-display area NDA. The first scan driving portion SDC1 may be disposed on a side (e.g., the left side) of the display panel 100, and the second scan driving portion SDC2 may be disposed on another side (e.g., the right side) of the display panel 100 but are not limited thereto. Each of the first scan driving portion SDC1 and the second scan driving portion SDC2 may be electrically connected to the display driving circuit 250 through scan fan out lines. Each of the first scan driving portion SDC1 and the second scan driving portion SDC2 may receive a scan control signal from the display driving circuit 250, generate scan signals according to the scan control signal, and output them to scan lines.

The sub-area SBA may protrude from a side of the main area MA in the second direction DR2. The length of the sub-area SBA in the second direction DR2 may be smaller than the length of the main area MA in the second direction DR2. The length in the first direction DR1 of the sub-area SBA may be less than the length in the first direction DR1 of the main area MA or may be substantially equal to the length in the first direction DR1 of the main area MA. The sub-area SBA may be curved and may be disposed at a lower portion of the display panel 100. For example, the sub-area SBA may overlap the main area MA in the third direction DR3.

The sub-area SBA may include a connection area CA, a pad area PA, and a bending area BA.

The connection area CA may be an area protruding from a side of the main area MA in the second direction DR2. A side of the connection area CA may be in contact with the non-display area NDA of the main area MA, and another side of the connection area CA may be in contact with the bending area BA.

The pad area PA may be an area where the pads PD and the display driving circuit 250 may be disposed. The display driving circuit 250 may be attached to the driving pads of the pad area PA using a conductive adhesive member such as an anisotropic conductive film. The circuit substrate 300 may be attached to the pads PD of the pad area PA using a conductive adhesive member such as an anisotropic conductive film. A side of the pad area PA may be in contact with the bending area BA.

The bending area BA may be a bent area. In case that the bending area BA is bent, the pad area PA may be disposed below the connection area CA and below the main area MA. The bending area BA may be disposed between the connection area CA and the pad area PA. A side of the bending area BA may be in contact with the connection area CA, and another side of the bending area BA may be in contact with the pad area PA.

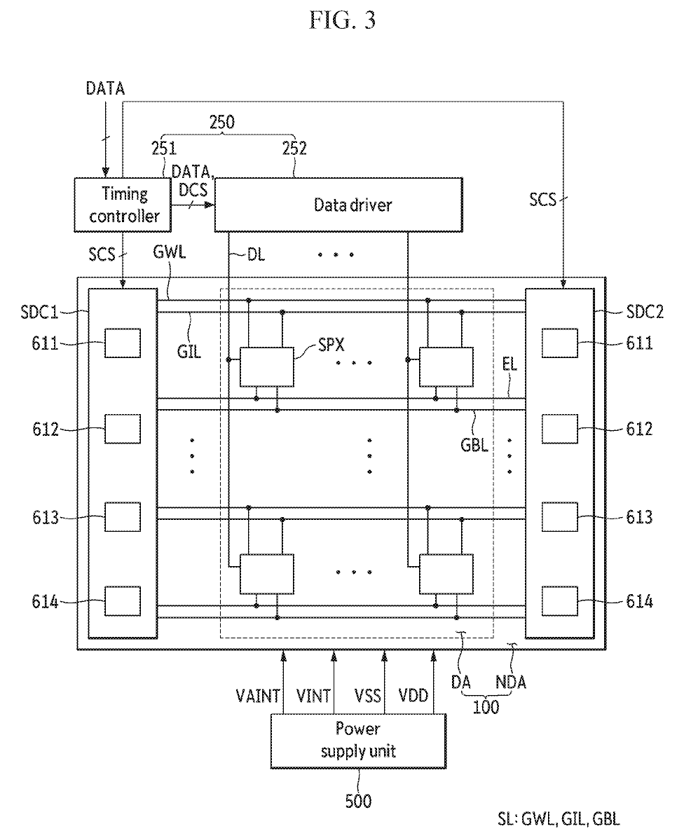

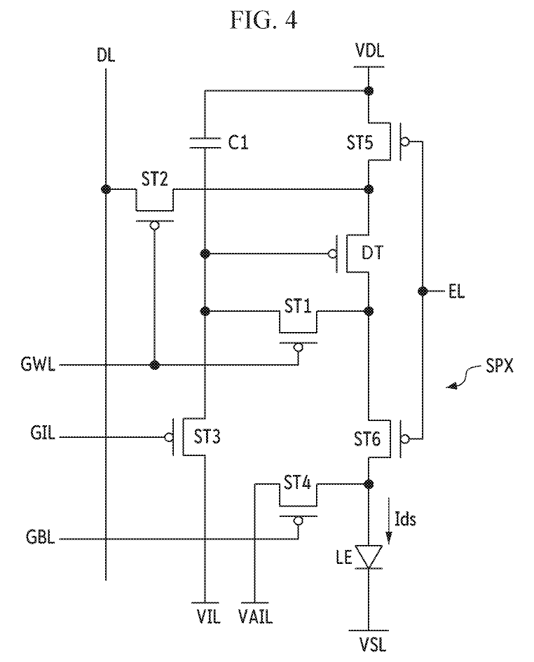

FIG. 3 is a schematic block diagram illustrating a display device according to one or more embodiments.

Referring to FIG. 3, the display area DA may include multiple pixels PX (each of the pixels PX including a plurality of sub-pixel SPX), multiple scan lines SL, multiple emission control lines EL, and multiple data lines DL.

Multiple pixels PX may be arranged in a matrix form along the first direction DR1 and the second direction DR2. For example, the plurality of pixels PX may be arranged along rows and columns of a matrix form along the first direction DR1 and the second direction DR2. Multiple scan lines SL and multiple emission control lines EL may extend in the first direction DR1 and be disposed along the second direction DR2. Multiple data lines DL may extend in the second direction DR2 and be disposed along the first direction DR1. Multiple scan lines SL may include a multiple write scan lines GWL, multiple initialization scan lines GIL, and multiple bias scan lines GBL.

Each of multiple sub-pixels SPX may be electrically connected to a write scan line GWL from among multiple write scan lines GWL, an initialization scan line GIL from among multiple initialization scan lines GIL, a bias scan line GBL from among multiple bias scan lines GBL, an emission control line EL from among multiple emission control lines EL, and a data line DL from among multiple data lines DL. Each of multiple sub-pixels SPX may be supplied with a data voltage of the data line DL according to the write scan signal of the write scan line GWL and may emit light emitting elements according to the data voltage.

The non-display area NDA may include a first scan driving portion SDC1, a second scan driving portion SDC2, and a display driving circuit 250.

Each of the first scan driving portion SDC1 and the second scan driving portion SDC2 may include a write scan signal output portion 611, an initialization scan signal output portion 612, a bias scan signal output portion 613, and an emission control signal output portion 614. Each of the write scan signal output portion 611, the initialization scan signal output portion 612, the bias scan signal output portion 613, and the emission control signal output portion 614 may receive a scan timing control signal SCS from a timing control circuit (e.g., a timing controller) 251.

The write scan signal output portion 611 may generate write scan signals according to the scan timing control signal SCS of the timing control circuit 251 and sequentially output them to the write scan lines GWL.

The initialization scan signal output portion 612 may generate initialization scan signals according to the scan timing control signal SCS and sequentially output them to the initialization scan lines GIL.

The bias scan signal output portion 613 may generate bias scan signals according to the scan timing control signal SCS and sequentially output them to the bias scan lines GBL. The emission control signal output portion 614 may generate emission control signals according to the scan timing control signal SCS and sequentially output them to the emission control lines EL.

The display driving circuit 250 may include a timing control circuit (e.g., a timing controller) 251 and a data driving circuit (e.g., a data driver) 252.

The data driving circuit 252 may receive digital video data DATA and a data timing control signal DCS from the timing control circuit 251. The data driving circuit 252 converts digital video data DATA into analog data voltages according to the data timing control signal DCS and outputs them to the data lines DL. For example, the sub-pixels SPX may be selected by the write scan signals of the first scan driving portion SDC1 and the second scan driving portion SDC2, and data voltages may be supplied to the selected sub-pixels SPX.

The timing control circuit 251 may receive digital video data DATA and timing signals from the outside. The timing control circuit 251 may generate a scan timing control signal SCS and a data timing control signal DCS for controlling the display panel 100 according to the timing signals. The timing control circuit 400 may output the scan timing control signal SCS to the first scan driving portion SDC1 and the second scan driving portion SDC2. The timing control circuit 251 may output digital video data DATA and a data timing control signal DCS to the data driving circuit 252.

The power supply circuit (e.g., a power supply unit) 500 may generate multiple panel driving voltages according to a power voltage supplied from the outside. For example, the power supply circuit 500 may generate a first power supply voltage VDD, a second power supply voltage VSS, a third power supply voltage VINT, and a fourth power supply voltage VAINT and supply them to the display panel 100.

FIG. 4 is a schematic diagram of an equivalent circuit of a sub-pixel according to one or more embodiments.

Referring to FIG. 4, a sub-pixel SPX according to one or more embodiments may be electrically connected to scan lines GWL, GIL, and GBL, an emission control line EL, and a data line DL. For example, the sub-pixel SPX may be electrically connected to a write scan line GWL, an initialization scan line GIL, a bias scan line GBL, an emission control line EL, and a data line DL.

The sub-pixel SPX according to one or more embodiments may include a driving transistor DT, switching elements, a capacitor, and a light emitting element LE. The switching elements include first to sixth transistors ST1, ST2, ST3, ST4, ST5, and ST6.

The driving transistor DT may include a gate electrode, a first electrode, and a second electrode. The driving transistor DT controls a drain-source current (Ids, hereinafter referred to as “driving current”) flowing between the first electrode and the second electrode according to a data voltage applied to a gate electrode of the driving transistor DT.

The light emitting element LE may be a micro light emitting diode.

The light emitting element LE emits light according to the driving current Ids. The amount of light emitted from the light emitting element LE may be proportional to the driving current Ids. The anode electrode of the light emitting element LE may be electrically connected to the first electrode of the fourth transistor ST4 and the second electrode of the sixth transistor ST6, and the cathode electrode may be electrically connected to a second power supply line VSL to which a second power supply voltage is applied.

A capacitor C1 may be formed between the gate electrode of a driving transistor DT and a first power supply line VDL to which a first power supply voltage is applied. The first power supply voltage may be a voltage of a higher level than the second power supply voltage. An electrode of the capacitor C1 may be electrically connected to the gate electrode of the driving transistor DT, and another electrode may be electrically connected to the first power supply line VDL.

As shown in FIG. 4, the first to sixth transistors ST1, ST2, ST3, ST4, ST5, and ST6 and the driving transistor DT may all be formed as p-type MOSFET. For example, the active layer of each of the first to sixth transistors ST1, ST2, ST3, ST4, ST5, and ST6 and the driving transistor DT may be formed of polysilicon.

The gate electrode of the first transistor ST1 and the gate electrode of the second transistor ST2 may be connected to the write scan line GWL, the gate electrode of the third transistor ST3 may be connected to the initialization scan line GIL, and the gate electrode of the fourth transistor ST4 may be connected to the bias scan line GBL. Because the first to sixth transistors ST1, ST2, ST3, ST4, ST5, and ST6 may be formed as p-type MOSFET and they may be turned on in case that a scan signal of a gate low voltage and an emission control signal are applied to the initialization scan line GIL, the write scan line GWL, the bias scan line GBL, and the emission control line EL, respectively. An electrode of the third transistor ST3 may be connected to a first initialization voltage line VIL to which the third power supply voltage (VINT of FIG. 3) is applied, and an electrode of the fourth transistor ST4 may be connected to a second initialization voltage line VAIL to which the fourth power supply voltage (VAINT of FIG. 3) is applied. The third power supply voltage (VINT of FIG. 3) and the fourth power supply voltage (VAINT of FIG. 3) may be different voltages. Further, the third power supply voltage (VINT in FIG. 3) and the fourth power supply voltage (VAINT in FIG. 3) may be voltages at a lower level than the first power supply voltage VDD and at a higher level than the second power supply voltage VSS.

In one or more other embodiments, the driving transistor DT, the second transistor ST2, the fourth transistor ST4, the fifth transistor ST5, and the sixth transistor ST6 may be formed of a p-type MOSFET, and the first transistor ST1 and the third transistor ST3 may be formed of an n-type MOSFET. For example, the active layers of each of the driving transistor DT, the second transistor ST2, the fourth transistor ST4, the fifth transistor ST5, and the sixth transistor ST6 formed of p-type MOSFETs may be formed of polysilicon, the active layers of each of the first transistor ST1 and the third transistor ST3 formed of an n-type MOSFET may be formed of an oxide semiconductor. Furthermore, because the first transistor ST1 and the third transistor ST3 may be formed as n-type MOSFET, the first transistor ST1 may be turned on in case that a scan signal of the gate high voltage is applied, and the third transistor ST3 may be turned on when an initialization scan signal of the gate high voltage is applied. In contrast, the second transistor ST2, the fourth transistor ST4, the fifth transistor ST5, and the sixth transistor ST6 may be formed as p-type MOSFET so that they may be turned on in case that a scan signal of the gate low voltage and a light emission control signal of a gate low voltage are applied.

In one or more other embodiments, the fourth transistor ST4 may be formed as an n-type MOSFET, and the remaining transistors DT, ST1, ST2, ST3, ST5, and ST6 may be formed as p-type MOSFET, in which case the active layer of the fourth transistor ST4 may be formed as an oxide semiconductor, and the active layers of each of the remaining transistors DT, ST1, ST2, ST3, ST5, and ST6 may be formed as polysilicon. Further, the fourth transistor ST4 may be turned on in case that a scan signal of a gate high voltage is applied, whereas the remaining transistors DT, ST1, ST2, ST3, ST5, and ST6 may be turned on in case that a scan signal of a gate low voltage and a light emission control signal are applied.

In one or more embodiments, the first to sixth transistors ST1, ST2, ST3, ST4, ST5, and ST6 and the driving transistor DT may all be formed as n-type MOSFET. For example, the active layer of each of the first to sixth transistors ST1, ST2, ST3, ST4, ST5, and ST6 and the driving transistor DT may be formed of an oxide semiconductor and may be turned on in case that a scan signal of a gate high voltage and a light emission control signal are applied.

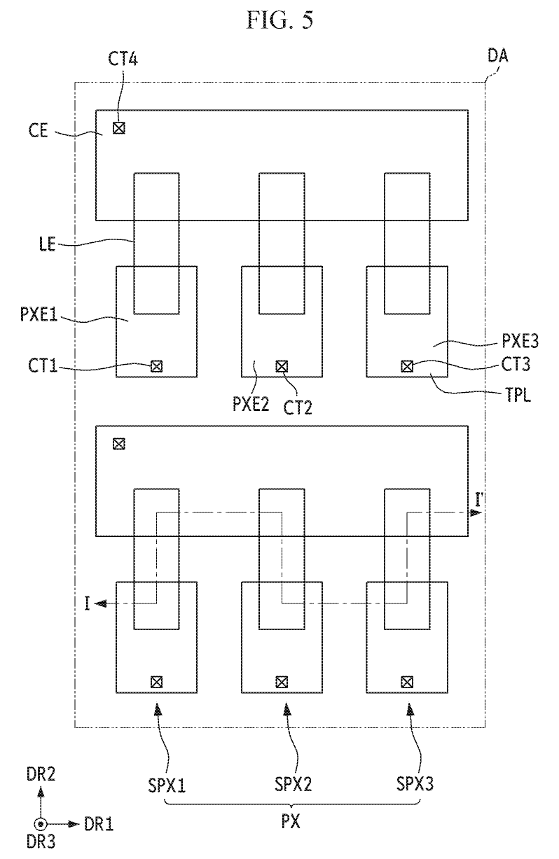

FIG. 5 is a layout diagram illustrating pixels of a display area according to one or more embodiments.

Referring to FIG. 5, each of the plurality of pixels PX of the display area DA may include three sub-pixels SPX1, SPX2, and SPX3, but the present disclosure is not limited thereto and may include four sub-pixels. When each of the plurality of pixels PX includes three sub-pixels, the three sub-pixels may be the first sub-pixel SPX1, the second sub-pixel SPX2, and the third sub-pixel SPX3.

The plurality of pixels PX may be arranged in a matrix form. In each of the plurality of pixels PX, the first sub-pixel SPX1, the second sub-pixel SPX2, and the third sub-pixel SPX3 may be arranged along a first direction DR1.

When each of the plurality of pixels PX includes three sub-pixels SPX1, SPX2, and SPX3, the first sub-pixel SPX1 may emit light of a first color, the second sub-pixel SPX2 may emit light of a second color, and the third sub-pixel SPX3 may emit light of a third color. Here, the light of the first color may be light in a red wavelength band, the light of the second color may be light in a green wavelength band, and the light of the third color may be light in a blue wavelength band. For example, the blue wavelength band may refer to light whose main peak wavelength is included in a wavelength band of about 370nm to 460nm, the green wavelength band may refer to light whose main peak wavelength is included in a wavelength band of about 480nm to 560nm, and the red wavelength band may refer to light whose main peak wavelength is included in a wavelength band of about 600nm to 750nm.

Alternatively, when each of the plurality of pixels PX includes four sub-pixels, the first sub-pixel may emit light of a first color, the second and fourth sub-pixels may emit light of a second color, and the third sub-pixel may emit light of a third color. Alternatively, the first sub-pixel may emit light of a first color, the second sub-pixel may emit light of a second color, the third sub-pixel may emit light of a third color, and the fourth sub-pixel may emit light of a fourth color. In this case, the fourth color light may be white light.

The first sub-pixel SPX1 includes a first pixel electrode PXE1, light emitting elements LE, and a common electrode CE. The second sub-pixel SPX2 includes a second pixel electrode PXE2, light emitting elements LE, and a common electrode CE. The third sub-pixel SPX3 includes a third pixel electrode PXE3, light emitting elements LE, and a common electrode CE. The common electrode CE may be an electrode commonly provided in the same column.

In each of the first sub-pixel SPX1, the second sub-pixel SPX2, and the third sub-pixel SPX3, the pixel electrodes PXE1, PXE2, and PXE3 and the common electrode CE may be arranged along the second direction DR2. Each of the pixel electrodes PXE1, PXE2, and PXE3 and the common electrodes CE may have a rectangular plane shape. The sizes of each of the first sub-pixel SPX1, the second sub-pixel SPX2, and the third sub-pixel SPX3 may be the same but are not limited thereto.

Each of the pixel electrodes PXE1, PXE2, and PXE3 may be electrically connected to at least one transistor through the pixel connection hole CT1, CT2, and CT3. For example, each of the pixel electrodes PXE1, PXE2, and PXE3 may be electrically connected to the first electrode of the fourth transistor (ST4 in FIG. 4) and the second electrode of the sixth transistor (ST6 in FIG. 4) of the corresponding sub-pixel.

The common electrode CE may be connected to a second power supply line VSL to which a second driving voltage VSS is applied through a first common connection hole CT4. Therefore, the second driving voltage VSS may be applied to each of the common electrodes CE. The pixel electrodes PXE1, PXE2, and PXE3 may be referred to as anode electrodes or first electrodes, and the common electrodes CE may be referred to as cathode electrodes or second electrodes.

A plurality of light emitting elements LE may be arranged on the pixel electrodes PXE1, PXE2, and PXE3 and the common electrode CE. Each of the plurality of light emitting elements LE may have a rectangular planar shape, but the present disclosure is not limited thereto. For example, each of the plurality of light emitting elements LE may have a circular planar shape.

When all the light emitting elements LE of each sub-pixel SPX1, SPX2, and SPX3 emit light of a blue wavelength, a light wavelength conversion layer that converts the light wavelength may be added on top of the light emitting elements LE. For example, a light wavelength conversion layer that converts blue light to red may be arranged on top of the light emitting element LE of the first sub-pixel SPX1, and a light wavelength conversion layer that converts blue light to green may be arranged on top of the light emitting element LE of the second sub-pixel SPX2.

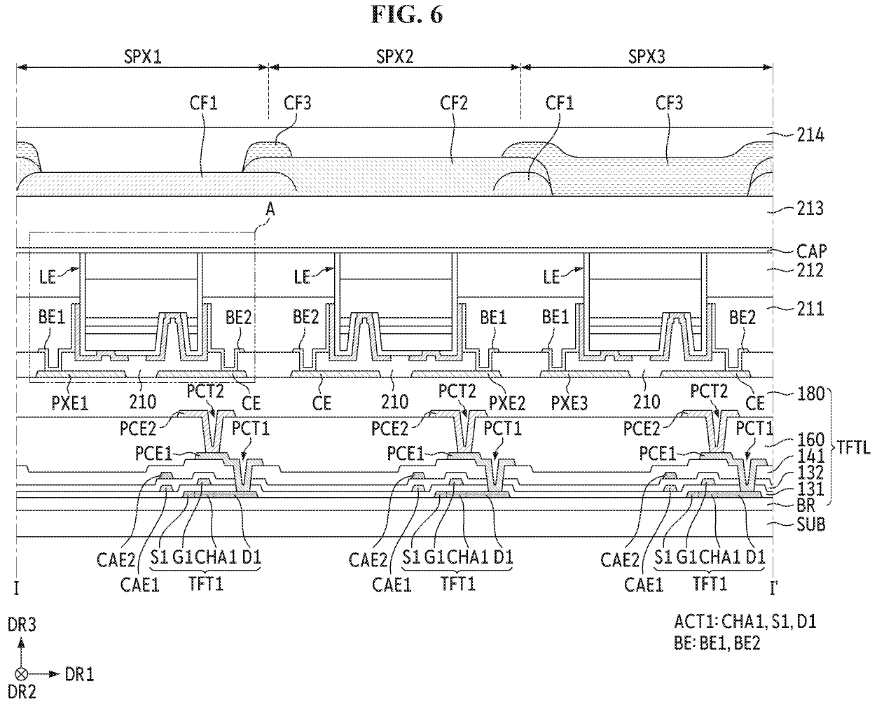

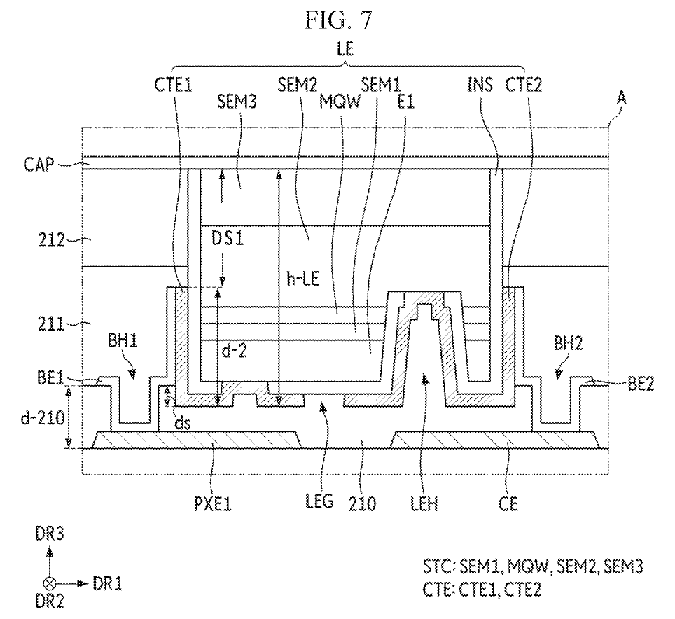

FIG. 6 is a cross-sectional view illustrating an example cross-section of one include panel corresponding to the lines I-I’ in FIG. 5. FIG. 7 is a cross-sectional view illustrating an example of an area A in FIG. 6 in detail.

Referring to FIGS. 6 – 7, a substrate SUB may be made of an insulating material such as glass, polymer resin, or the like. If the substrate SUB is made of polymer resin, it may be a flexible substrate that may be stretched. The polymer resin may be acrylic resin, epoxy resin, phenolic resin, polyamide resin, polyimide resin, and/or the like.

A barrier film BR may be arranged on the substrate SUB. The barrier film BR is a film to protect thin-film transistors TFT1 of the thin-film transistor layer TFTL from moisture penetrating through the substrate SUB that is vulnerable to moisture permeation. The barrier film BR may be formed of a plurality of inorganic films that are alternately stacked.

A thin-film transistor TFT1 may be arranged on the barrier film BR. The thin-film transistor TFT1 may be either the fourth transistor ST4 or the sixth transistor ST6 shown in FIG. 4. The thin-film transistor TFT1 may include a first active layer ACT1 and a first gate electrode G1.

The first active layer ACT1 of the thin-film transistor TFT1 may be arranged on the barrier film BR. The first active layer ACT1 of the thin-film transistor TFT1 may include polycrystalline silicon, monocrystalline silicon, low-temperature polycrystalline silicon, and/or amorphous silicon. Alternatively, the first active layer ACT1 of the thin-film transistor TFT1 may include an oxide semiconductor including IGZO (indium (In), gallium (Ga), zinc (Zn), and oxygen (O)), IGZTO (indium (In), gallium (Ga), zinc (Zn), tin (Sn), and oxygen (O)), or IGTO (indium (In), gallium (Ga), tin (Sn), and oxygen (O)).

The first active layer ACT1 may include a first channel area CHA1, a first source area S1, and a first drain area D1. The first channel area CHA1 may be an area overlapping the first gate electrode G1 in the third direction DR3, which is the thickness direction of the substrate SUB. The first source area S1 may be arranged on one side of the first channel area CHA1, and the first drain area D1 may be arranged on the other side of the first channel area CHA1. The first source area S1 and the first drain area D1 may be areas that do not overlap with the first gate electrode G1 in the third direction DR3. The first source area S1 and the first drain area D1 may be conductive areas in which semiconductor materials are doped with ions.

A first gate insulating film 131 may be arranged on the first channel area CHA1, the first source area S1, and the first drain area D1 of the thin-film transistor TFT1 and on the barrier film BR.

A first gate metal layer may be arranged on the first gate insulating film 131. The first gate metal layer may include a first gate electrode G1 of a thin-film transistor TFT1 and a first capacitor electrode CAE1. The first gate electrode G1 may overlap the first active layer ACT1 in the third direction DR3. Although the first gate electrode G1 and the first capacitor electrode CAE1 are illustrated as being arranged apart (e.g., spaced apart) from each other in FIG. 6, the first gate electrode G1 and the first capacitor electrode CAE1 may be connected to each other.

A second gate insulating film 132 may be arranged on the first gate electrode G1 and the first capacitor electrode CAE1 of the thin-film transistor TFT1 and on the first gate insulating film 131.

A second gate metal layer may be arranged on the second gate insulating film 132. The second gate metal layer may include a second capacitor electrode CAE2. The second capacitor electrode CAE2 may overlap the first capacitor electrode CAE1 of the thin-film transistor TFT1 in the third direction DR3. Because the second gate insulating film 132 has a suitable dielectric constant (e.g., a predetermined dielectric constant), the capacitor (C1 in FIG. 4) may be formed by the first capacitor electrode CAE1, the second capacitor electrode CAE2, and the second gate insulating film 132 arranged between them.

A first interlayer insulating film 141 may be arranged on the second capacitor electrode CAE2 and on the second gate insulating film 132.

A first data metal layer may be arranged on the first interlayer insulating film 141. The first data metal layer may include a first source connection electrode PCE1. The first source connection electrode PCE1 may be connected to the first drain area D1 of the first active layer ACT1 through a first source contact hole PCT1 penetrating the first gate insulating film 131, the second gate insulating film 132, and the interlayer insulating film 141.

A first planarization organic film 160 may be arranged on the first source connection electrode PCE1 and on the first interlayer insulating film 141 to planarize a step caused by the thin-film transistor TFT1.

A second data metal layer may be arranged on the first planarization organic film 160. The second data metal layer may include a second source connection electrode PCE2. The second source connection electrode PCE2 may be connected to the first source connection electrode PCE1 through a second pixel contact hole (PCT2) penetrating the first planarization organic film 160.

A second planarization organic film 180 may be arranged on the second source connection electrode PCE2 and on the first planarization organic film 160.

The barrier film BR, the first gate insulating film 131, the second gate insulating film 132, and the interlayer insulating film 141 may be formed of an inorganic film, such as silicon nitride (SiNₓ), silicon oxide nitride (SiON), silicon oxide (SiOₓ), titanium oxide (TiOₓ), and/or aluminum oxide (AlOₓ).

The first gate metal layer, the second gate metal layer, the first data metal layer, and the second data metal layer may be formed as a single layer or multiple layers of molybdenum (Mo), aluminum (Al), chromium (Cr), gold (Au), titanium (Ti), nickel (Ni), neodymium (Nd), and/or copper (Cu), and/or an alloy thereof.

The first planarization organic film 160 and the second planarization organic film 180 may be formed of an organic film such as an acrylic resin, an epoxy resin, a phenolic resin, a polyamide resin, a polyimide resin, and/or the like.

A light emitting element layer may be arranged on the second planarization organic film 180. The light emitting element layer may include pixel electrodes PXE1, PXE2, and PXE3, light emitting elements LE, a common electrode CE, and a first organic layer 210.

A pixel electrode layer including pixel electrodes PXE1, PXE2, and PXE3 and common electrodes CE1, CE2, and CE3 may be arranged on a second planarization organic film 180.

Each of the first pixel electrode PXE1, the second pixel electrode PXE2, and the third pixel electrode PXE3 may be connected to the second source connection electrode PCE2 through connection holes (CT1/CT2/CT3 in FIG. 5) penetrating the second planarization organic film 180. Each of the pixel electrodes PXE1, PXE2, and PXE3 may be connected to the first source region S1 or the first drain region D1 of the thin-film transistor TFT1 through the first source connection electrode PCE1 and the second source connection electrode PCE2. Therefore, a voltage controlled by the thin-film transistor TFT1 may be applied to each of the pixel electrodes PXE1, PXE2, and PXE3.

The common electrodes CE may be connected to a second power supply line (VSL in FIG. 4) to which a second driving voltage (VSS in FIG. 3) is applied through a common connection hole (CT4 in FIG. 5). Therefore, the second driving voltage VSS may be applied to each of the common electrodes CE.

The pixel electrode layer may be formed as a single layer or multiple layers made of molybdenum (Mo), aluminum (Al), chromium (Cr), gold (Au), titanium (Ti), nickel (Ni), neodymium (Nd), and/or copper (Cu), and/or an alloy thereof. For example, the pixel electrode layer may be made of copper (Cu) having a low surface resistance to lower the resistance of each of the pixel electrodes PXE1, PXE2, and PXE3 and the common electrode CE.

A first organic layer 210 may be arranged on the pixel electrode layer. The first organic layer 210 temporarily fixes or adheres the plurality of light emitting elements LE to prevent the plurality of light emitting elements LE from tilting and falling over or collapsing during the process of transferring the plurality of light emitting elements LE to the display panel 100. That is, the first organic layer 210 may be a film for temporarily adhering the plurality of light emitting elements LE onto each of the pixel electrodes PXE1, PXE2, and PXE3. To facilitate the temporary adhesion, the thickness of the first organic layer 210 may be greater than the thickness of each of the pixel electrodes PXE1, PXE2, and PXE3 and may be greater than the thickness of the contact electrode CTE. For example, a thickness d-210 of the first organic layer 210 may be about 1㎛ or more and 3μm or less. Here, the thickness may mean the length in the direction perpendicular to the substrate SUB (e.g., in the third direction DR3).

The first organic layer 210 may be a photosensitive organic film such as a photoresist. Alternatively, the first organic layer 210 may be formed of an acrylic resin, an epoxy resin, a phenolic resin, a polyamide resin, a polyimide resin, and/or the like.

The plurality of light emitting elements LE may be arranged on the first organic layer 210. The plurality of light emitting elements LE arranged on the first organic layer 210 may be embedded in the first organic layer 210. For example, at least a portion of the side surfaces of the plurality of light emitting elements LE are located within the first organic layer 210.

In FIGS. 6 and 7, the light emitting element LE may be a flip-type micro LED. The flip-type micro LED refers to an LED in which contact electrodes CTE1 and CTE2 are formed on one side (e.g., the bottom side) of the light emitting element LE.

The light emitting element LE may have various shapes, such as a shape of a rod, wire, tube, etc., a shape of a polygonal column such as a cube, a rectangular parallelepiped, a hexagonal column, etc., or a shape that extends in one direction but has a partially inclined outer surface.

Each of the plurality of light emitting elements LE may be formed of an inorganic material such as gallium nitride (GaN).

Each of the plurality of light emitting elements LE may be formed by growing on a semiconductor substrate such as a silicon substrate or a sapphire substrate. The plurality of light emitting elements LE may be transferred onto the pixel electrode layer of the display panel 100 directly from the semiconductor substrate or through a relay substrate. Alternatively, the plurality of light emitting elements LE may be transferred onto the pixel electrodes PXE1, PXE2, and PXE3 of the display panel 100 by an electrostatic method using an electrostatic head or a stamp method using an elastic polymer material such as PDMS (Polydimethylsiloane) or silicon as a transfer substrate.

Each of the plurality of light emitting elements LE may include a conductive layer E1, a first semiconductor layer SEM1, an active layer MQW, a second semiconductor layer SEM2, a protective film INS, a first contact electrode CTE1, and a second contact electrode CTE2.

The conductive layer E1 may be arranged on the bottom surface of the first semiconductor layer SEM1. In FIG. 7, the conductive layer E1 is illustrated as covering the entire bottom surface of the first semiconductor layer SEM1, but the present disclosure is not limited thereto. For example, the conductive layer E1 may be arranged on a portion of the bottom surface of the first semiconductor layer SEM1. The conductive layer E1 may include molybdenum (Mo), aluminum (Al), chromium (Cr), gold (Au), titanium (Ti), nickel (Ni), neodymium (Nd), and/or copper (Cu).

The first semiconductor layer SEM1 may be arranged on the conductive layer E1. The first semiconductor layer SEM1 may be formed of a semiconductor material layer doped with a first conductive dopant, such as magnesium (Mg), zinc (Zn), calcium (Ca), strontium (Sr), barium (Ba), and/or the like, for example, gallium nitride (GaN).

The active layer MQW may be arranged on the first semiconductor layer SEM1. The active layer MQW may emit light by combining electron-hole pairs according to an electrical signal applied through the first semiconductor layer SEM1 and the second semiconductor layer SEM2.

The active layer MQW may include a material having a single or multi-quantum well structure. When the active layer MQW includes a material having a multi-quantum well structure, it may have a structure in which a plurality of well layers and barrier layers are alternately stacked. At this time, the well layer may be formed of indium gallium nitride (InGaN), and the barrier layer may be formed of gallium nitride (GaN) and/or aluminum gallium nitride (AlGaN), but the present disclosure is not limited thereto.

Alternatively, the active layer MQW may have a structure in which semiconductor materials having a high band gap energy and semiconductor materials having a low band gap energy are alternately stacked with each other, may include other Group III to Group V semiconductor materials according to the wavelength range of emitted light.

In one or more embodiments, when the active layer MQW includes InGaN, the color of the emitted light may vary depending on the content of indium (In). For example, as the content of indium (In) increases, the wavelength band of light emitted by the active layer may shift to the red wavelength band, and as the content of indium (In) decreases, the wavelength band of light emitted by the active layer may shift to the blue wavelength band. For example, the content of indium (In) in the active layer MQW of the light emitting element LE that emits the third light (e.g., light in the blue wavelength band) may be approximately 10wt% to 20wt%.

The second semiconductor layer SEM2 may be arranged on the active layer MQW. The second semiconductor layer SEM2 may be a semiconductor material layer doped with a second conductive dopant such as silicon (Si), germanium (Ge), tin (Sn), and/or the like, for example gallium nitride (GaN).

An electron blocking layer may be arranged between the first semiconductor layer SEM1 and the active layer MQW. The electron blocking layer may be a layer to suppress or prevent too many electrons from flowing into the active layer MQW. For example, the electron blocking layer may be aluminum gallium nitride (AlGaN) or p-type aluminum gallium nitride (AlGaN) doped with p-type magnesium (Mg). The electronic blocking layer may be omitted.

A superlattice layer may be arranged between the active layer MQW and the second semiconductor layer SEM2. The superlattice layer may be a layer for relieving stress between the second semiconductor layer SEM2 and the active layer MQW. For example, the superlattice layer may be aluminum gallium nitride (AlGaN) or p-type aluminum gallium nitride (AlGaN) doped with p-type magnesium (Mg). The superlattice layer may be omitted.

In one or more embodiments, a third semiconductor layer SEM3 may be further arranged on one surface of the second semiconductor layer SEM2. The third semiconductor layer may be a semiconductor material layer having an n-type dopant lower than a suitable threshold value (e.g., a predetermined threshold value) and may be referred to as an undoped semiconductor layer. For example, the third semiconductor layer may be indium aluminum gallium nitride (InAlGaN), gallium nitride (GaN), aluminum gallium nitride (AlGaN), indium gallium nitride (InGaN), aluminum nitride (AlN), and/or indium nitride (InN), having an n-type dopant lower than a suitable threshold value (e.g., a predetermined threshold value).

The protective film INS may be a film for protecting the bottom surface and the side surface of the light emitting element LE. The protective film INS may be arranged on the bottom surface and the side surface of the conductive layer E1 and the side surface of the semiconductor and active layers SEM1, MQW, SEM2, and SEM3. Specifically, the protective film INS may be arranged on the bottom surface and side surface of the conductive layer E1, the side surface of the first semiconductor layer SEM1, the side surface of the active layer MQW, the side surface of the second semiconductor layer SEM2, and the side surface of the third semiconductor layer SEM3.

The protective film INS may be formed of an inorganic film, such as silicon nitride (SiNₓ), silicon oxide nitride (SiON), silicon oxide (SiOₓ), titanium oxide (TiOₓ), and/or aluminum oxide (AlOₓ). The protective film INS is preferably arranged from one end to the other end of the side surface of the light emitting element LE but may be arranged with a gap from one end due to process error.

A hole LEH may be formed that penetrates the conductive layer E1, the first semiconductor layer SEM1, and the active layer MQW of the light emitting element LE to expose the second semiconductor layer SEM2. The hole LEH may have a rectangular planar shape, but the present disclosure is not limited thereto. For example, the hole LEH may have a planar shape of a polygon, such as a circle, an ellipse, and/or a square.

In addition, the protective film INS may be arranged on the sidewall of the conductive layer E1 exposed in the hole LEH, the sidewall of the first semiconductor layer SEM1, and the sidewall of the active layer MQW. The protective film INS may not cover the second semiconductor layer SEM2 in the hole LEH. Therefore, the second semiconductor layer SEM2 exposed by the hole LEH may be exposed without being covered by the protective film INS.

The first contact electrode CTE1 may be arranged on at least one side surface and the bottom surface of the element rod STC (e.g., STC: SEM1, MQW, SEM2, SEM3). The first contact electrode CTE1 may be arranged on the bottom surface of the conductive layer E1 arranged without being covered by the protective film INS and may extend to the side surface of the element rod STC. The first contact electrode CTE1 may be electrically connected to the conductive layer E1.

The second contact electrode CTE2 may be arranged on at least one side and the bottom surface of the element rod STC. At this time, the first contact electrode CTE1 may be arranged on the first side of the element rod STC and the first side of the conductive layer E1, while the second contact electrode CTE2 may be arranged on the second side of the element rod STC and the second side of the conductive layer E1.

The second contact electrode CTE2 may be arranged on the protective film INS arranged in the hole LEH and the second semiconductor layer SEM2 exposed in the hole LEH without being covered by the protective film INS. Therefore, the second contact electrode CTE2 may be electrically connected to the second semiconductor layer SEM2 in the hole LEH. The hole LEH of the light emitting element LE may be filled with the first organic layer 210.

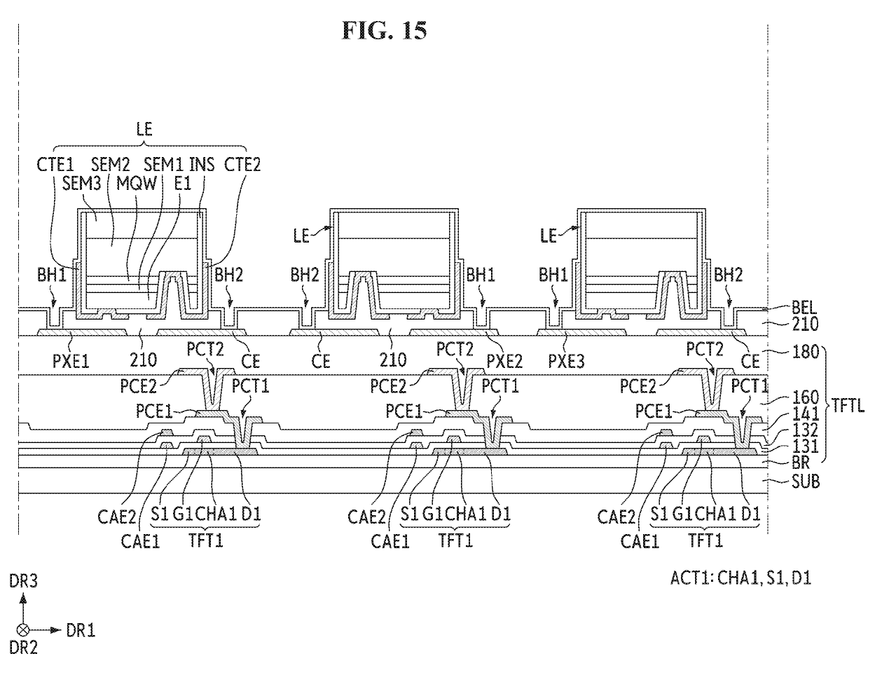

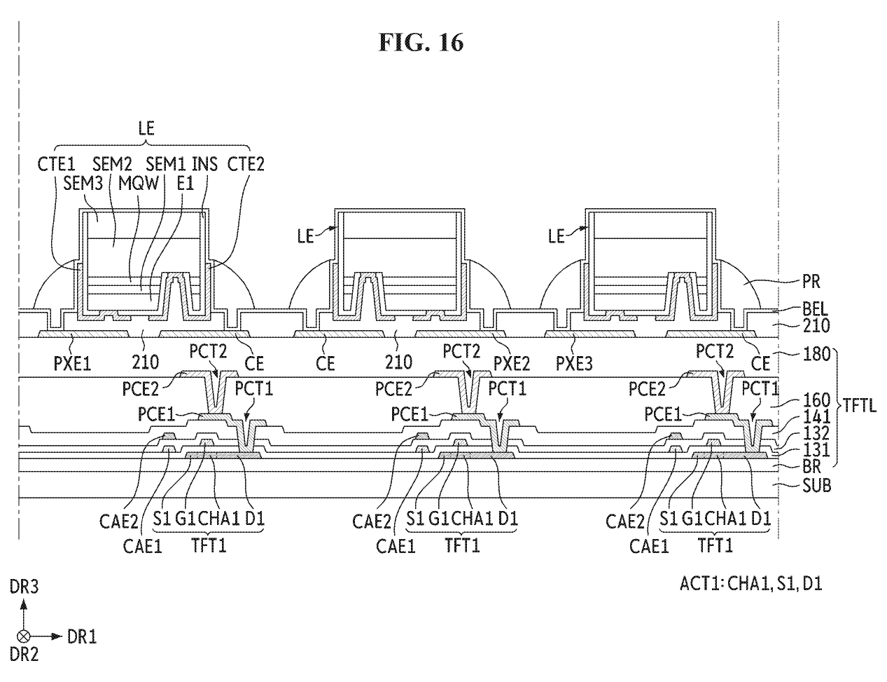

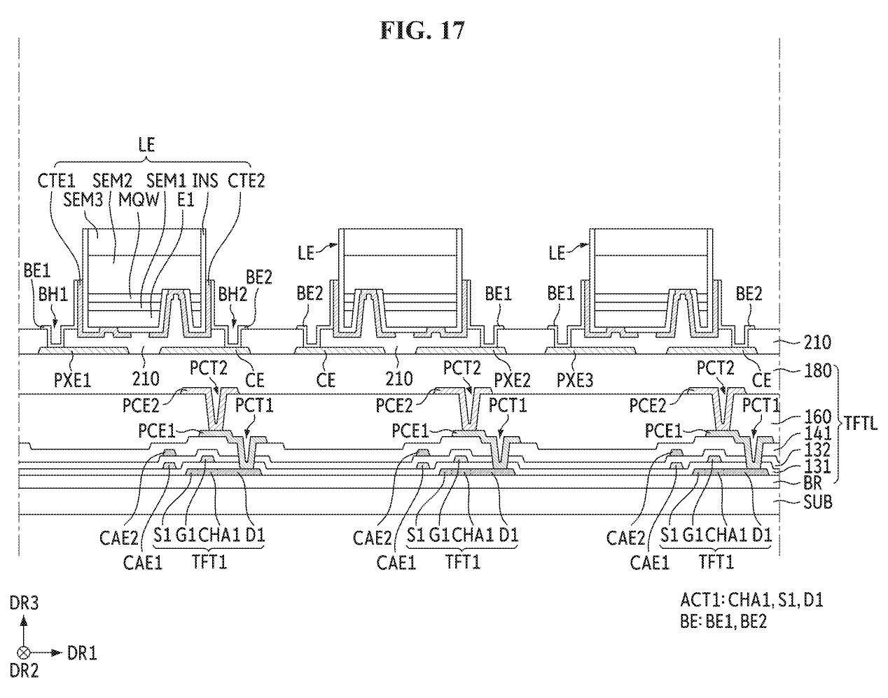

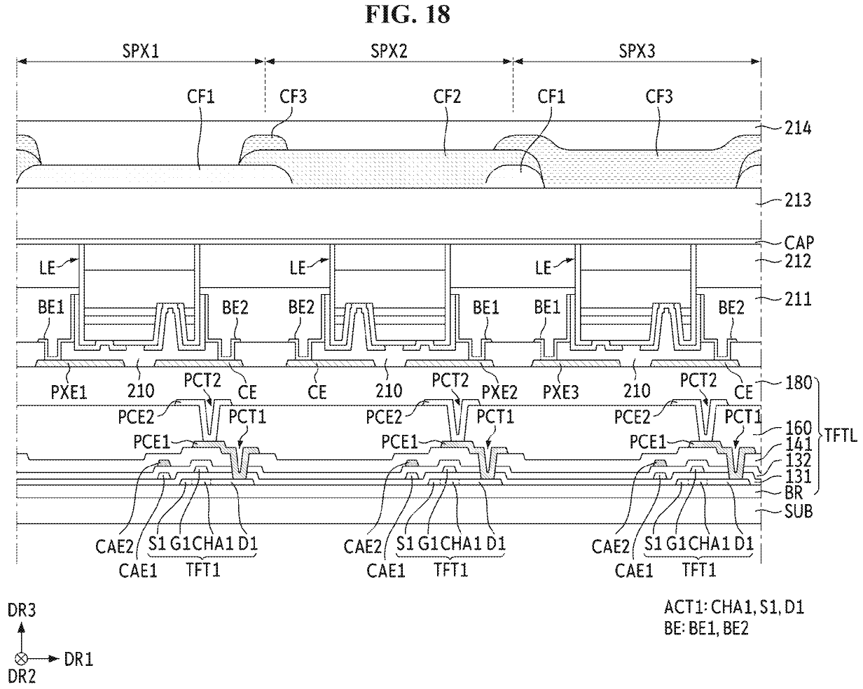

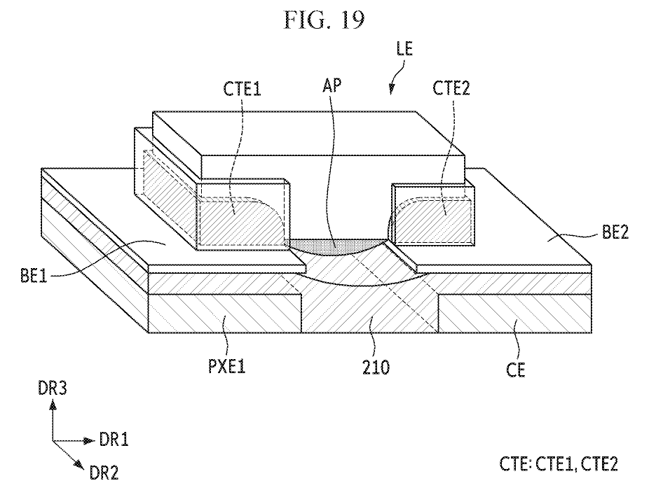

The first contact electrode CTE1 and the second contact electrode CTE2 are spaced (e.g., spaced apart) from each other on one side of the light emitting element LE and are not electrically connected to each other. Further, the one side of the light emitting element LE and the contact electrodes CTE1 and CTE2 have a certain thickness. Due to this thickness, a concave region is formed on the inside of the light emitting element between the first contact electrode CTE1 and the second contact electrode CTE2, and it may be defined as a groove LEG of the light emitting element LE. The groove LEG has a specific depth. The first organic layer 210 is filled inside the groove LEG. If the first organic layer 210 is not filled inside the groove LEG, the etchant may enter the groove LEG during the process of forming the connection electrodes BE1 and BE2, which may cause short circuiting of the connection electrodes BE1 and BE2. The explanation is described in detail with reference to FIG. 19.

The first contact electrode CTE1 and the second contact electrode CTE2 may be arranged on at least a portion of a side surface of the element rod STC. A portion of the side surface of the element rod STC may be exposed without being covered by the first contact electrode CTE1 and the second contact electrode CTE2. For example, the height d-2 of the first contact electrode CTE1 and the second contact electrode CTE2 arranged on the side surface of the element rod STC may be approximately ½ (50%) or more of the height h-LE of the light emitting element LE. Further, approximately 10% or more and 60% or more of the first contact electrode CTE1 and the second contact electrode CTE2 arranged on the side surface of the light emitting element LE are positioned within the first organic layer 210. Preferably, the first contact electrode CTE1 and the second contact electrode CTE2 arranged on the side of the light emitting element LE are positioned within the first organic layer 210 by approximately 20% or more and approximately 40%. The first contact electrode CTE1 and the second contact electrode CTE2 being positioned within the first organic layer 210 means that they are embedded in the first organic layer 210. Accordingly, the first contact electrode CTE1 and the second contact electrode CTE2 arranged on the side of the light emitting element LE are embedded within the first organic layer 210 by approximately 20% or more and approximately 40%. In other words, the first contact electrode CTE1 and the second contact electrode CTE2 may be arranged to a height of approximately 10% to 60% of the first organic layer 210. For example, when the height h-LE of the light emitting element LE is approximately 6μm, the height d-2 of the first contact electrode CTE1 and the second contact electrode CTE2 arranged on the side of the light emitting element LE is approximately 3μm, and the depth ds embedded in the first organic layer 210 may be approximately 0.3μm or more and 1.8μm or less. Considering the process margin, the depth ds of the first contact electrode CTE1 and the second contact electrode CTE2 embedded in the first organic layer 210 may be approximately 0.6㎛ or more and 1.2μm or less.

If the depth ds of the first contact electrode CTE1 and the second contact electrode CTE2 embedded in the first organic layer 210 is less than approximately 10% of the height d-2 of the first contact electrode CTE1 and the second contact electrode CTE2, the light emitting element LE may not be firmly fixed to the first organic layer 210, which may cause defects such as shifting during alignment. Additionally, if the depth ds of the first contact electrode CTE1 and the second contact electrode CTE2 embedded in the first organic layer 210 exceeds approximately 60% of the height d-2 of the first contact electrode CTE1 and the second contact electrode CTE2, poor contact may occur between the connection electrodes BE1 and BE2 and the first contact electrode CTE1 and the second contact electrode CTE2, which may cause dark spots.

The first contact electrode CTE1 and the second contact electrode CTE2 may include molybdenum (Mo), aluminum (Al), chromium (Cr), gold (Au), titanium (Ti), nickel (Ni), neodymium (Nd), and/or copper (Cu). Specifically, the first contact electrode CTE1 and the second contact electrode CTE2 may be formed as a two-layer structure of chromium (Cr) and gold (Au), a three-layer structure of titanium (Ti), aluminum (Al), and titanium (Ti), or a three-layer structure of indium tin oxide (ITO), silver (Ag), and indium tin oxide (ITO) to increase reflectivity.

Each of the first contact electrode CTE1 and the second contact electrode CTE2 may be arranged on three sides of the element rod STC. For example, when the element rod STC includes first to fourth sides, the first contact electrode CTE1 may be arranged on the first side, the second side, and the third side, and the second contact electrode CTE2 may be arranged on the second side, the third side, and the fourth side.

The connection electrodes BE1 and BE2 electrically connect the light emitting element LE and the pixel electrode layer.

In one or more embodiments, the first connection electrode BE1 connects the first contact electrode CTE1 of the light emitting element LE and the pixel electrode PXE1, PXE2, and PXE3. The first connection electrode BE1 may be arranged on the first contact electrode CTE1 arranged on the side of the element rod STC. The first connection electrode BE1 may be connected to the pixel electrode PXE1, PXE2, and PXE3 exposed through a first connection hole BH1 penetrating the first organic layer 210. Further, the first connection electrode BE1 extends along the top surface of the first organic layer 210 and one side of the first contact electrode CTE1.

The second connection electrode BE2 may be arranged on the second contact electrode CTE2 arranged on the side of the element rod STC. The second connection electrode BE2 may be connected to the common electrode CE exposed through a second connection hole BH2 penetrating the first organic layer 210. Further, the second connection electrode BE2 extends along the top surface of the first organic layer 210 and one side of the second contact electrode CTE2.

In FIG. 7, as an example, the distance between the first connection electrode BE1 and the second connection electrode BE2 and the top surface of the light emitting element LE in the third direction DR3 is substantially the same as the distance between the first contact electrode CTE1 and the second contact electrode CTE2 and the top surface of the light emitting element LE, but the present disclosure is not limited thereto. For example, the distance between the first connection electrode BE1 and the second connection electrode BE2 and the top surface of the light emitting element LE in the third direction DR3 may be substantially the same as the distance DS1 between the first contact electrode CTE1 and the second contact electrode CTE2 and the top surface of the light emitting element LE.

The second organic layer 211 may be arranged to cover a portion of the side surfaces of the plurality of light emitting elements LE. Further, the second organic layer 211 may be arranged to cover the connection electrodes BE1 and BE2.

The third organic layer 212 may be arranged on the second organic layer 211. The third organic layer 212 may be arranged to cover another portion of the side surface of each of the plurality of light emitting elements LE. The third organic layer 212 may be arranged on the protective film INS that is exposed and not covered by the second organic layer 211 as shown in FIG. 7, but the present disclosure is not limited thereto. For example, a portion of the connection electrodes BE1 and BE2 may be covered by the second organic layer 211. The top surface of each of the plurality of light emitting elements LE may be exposed and not covered by the third organic layer 212.

The second organic layer 211 and the third organic layer 212 are layers for flattening the unevenness caused by the plurality of light emitting elements LE. When the height of the second organic layer 211 is arranged to cover most of the sides of each of the plurality of light emitting elements LE, the third organic layer 212 may be omitted.

The second organic layer 211 and the third organic layer 212 may be formed from organic films such as acrylic resin, epoxy resin, phenolic resin, polyamide resin, and/or polyimide resin.

A capping layer CAP may be arranged on the third organic layer 212 and the light emitting element LE.

The capping layer CAP may be formed of an inorganic film, such as silicon nitride (SiNₓ), silicon oxide nitride (SiON), silicon oxide (SiOₓ), titanium oxide (TiOₓ), and/or aluminum oxide (AlOₓ).

A fourth organic layer 213 may be arranged on the capping layer CAP. A plurality of color filters CF1, CF2, and CF3 may be arranged on the fourth organic layer 213. The plurality of color filters CF1, CF2, and CF3 may include first color filters CF1, second color filters CF2, and third color filters CF3.

The first color filter CF1 arranged in the first sub-pixel SPX1 may transmit the first light (e.g., light in the red wavelength band) and absorb or block other light. Therefore, the first sub-pixel SPX1 may emit the first light (e.g., light in the red wavelength band).

The second color filter CF2 arranged in the second sub-pixel SPX2 may transmit the second light (e.g., light in the green wavelength band) and absorb or block other light. Therefore, the second sub-pixel SPX2 may emit the second light (e.g., light of the green wavelength band).

The third color filter CF3 arranged in the third sub-pixel SPX3 may transmit the third light (e.g., light of the blue wavelength band). Therefore, the third sub-pixel SPX3 may emit the third light (e.g., light of the blue wavelength band).

The first color filter CF1, the second color filter CF2, and the third color filter CF3 overlapping in the third direction DR3 may overlap and function as a light blocking layer that blocks light.

A fifth organic layer 214 for planarization may be arranged on the plurality of color filters CF1, CF2, and CF3.

The fourth organic layer 213 and the fifth organic layer 214 may be formed of an acrylic resin, an epoxy resin, a phenolic resin, a polyamide resin, a polyimide resin, and/or the like.

In one or more embodiments, the light emitting elements LE of the first to third sub-pixels SPX1, SPX2, and SPX3 may emit light of the same color. In this case, at least one light conversion layer may be arranged on a light emitting element LE of the corresponding sub-pixel SPX to convert light emitted from the light emitting element LE of the corresponding sub-pixel SPX into light corresponding to the light emitting color of the corresponding sub-pixel SPX and at least one of the color filters may also be arranged on the light conversion layer. When the light emitting elements LE of the first to third sub-pixels SPX1, SPX2, and SPX3 emit light of the same color, the sizes of the light emitting elements LE of the first to third sub-pixels SPX1, SPX2, and SPX3 may be the same or different from each other. For example, depending on the light conversion efficiency by the light conversion layer, at least one of the sizes of the light emitting elements LE of the sub-pixels SPX and the areas of the light emitting areas of the sub-pixels SPX may be differentiated.

In one or more embodiments, the plurality of color filters CF1, CF2, and CF3 may be omitted.

The fourth organic layer 213 and the fifth organic layer 214 may be formed of an acrylic resin, an epoxy resin, a phenolic resin, a polyamide resin, a polyimide resin, and/or the like.

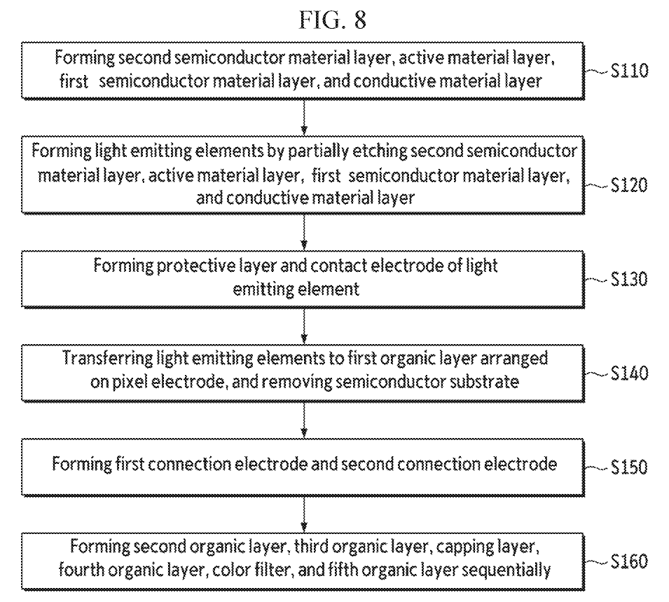

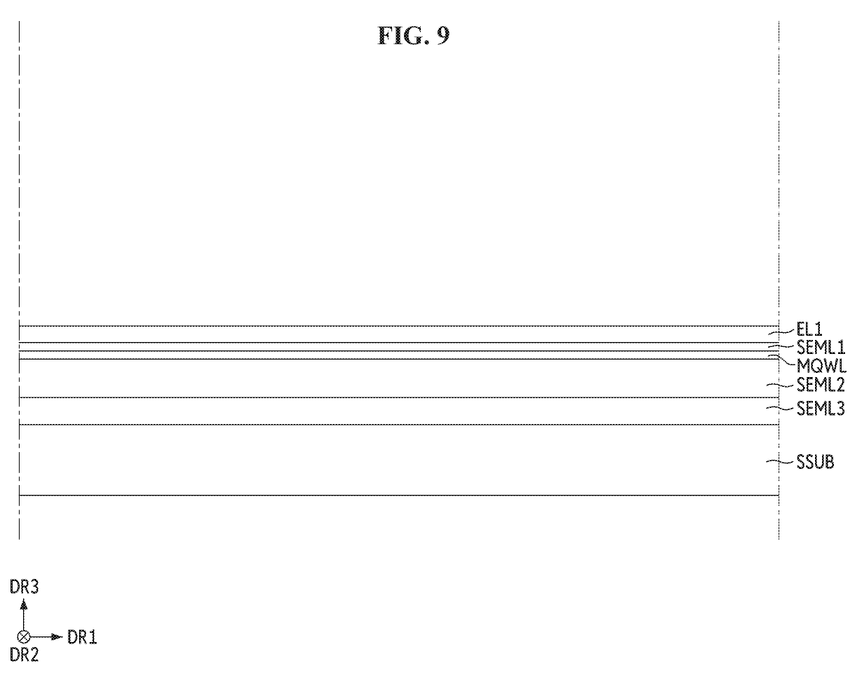

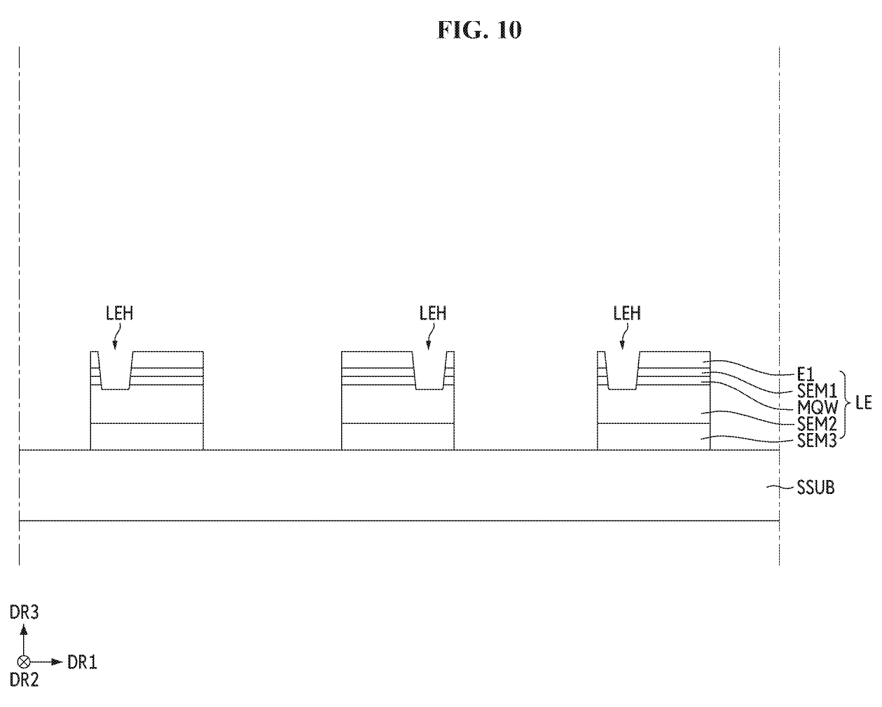

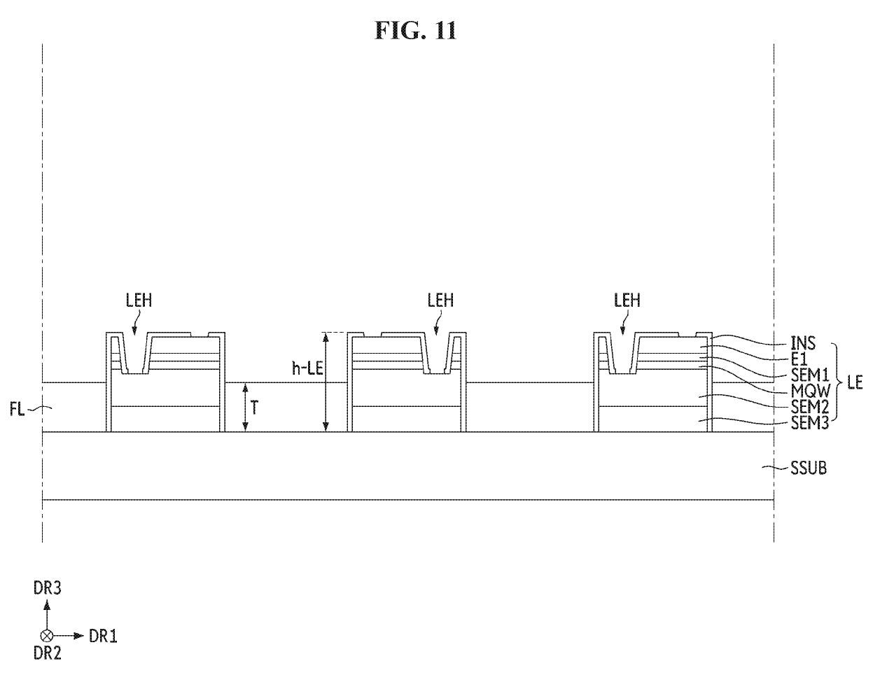

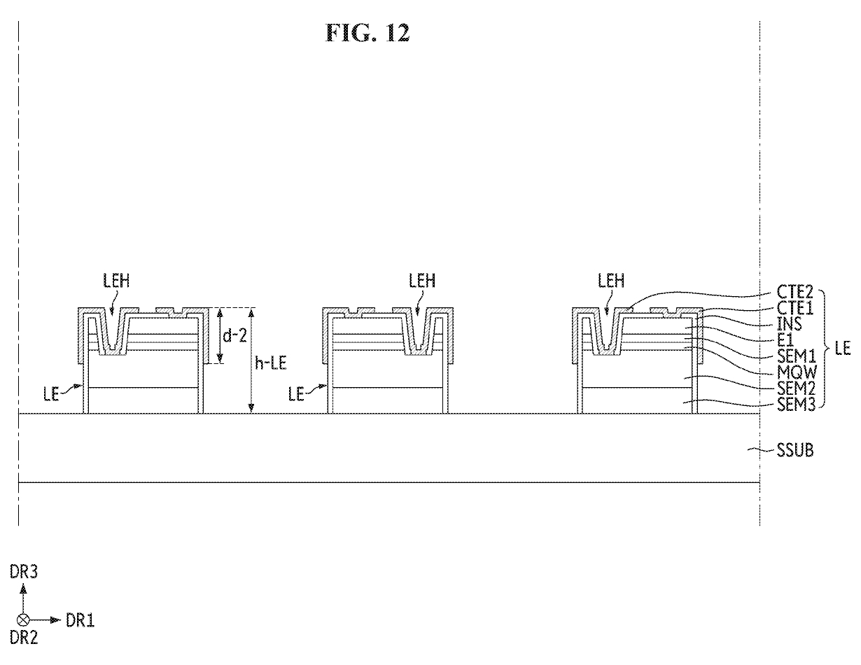

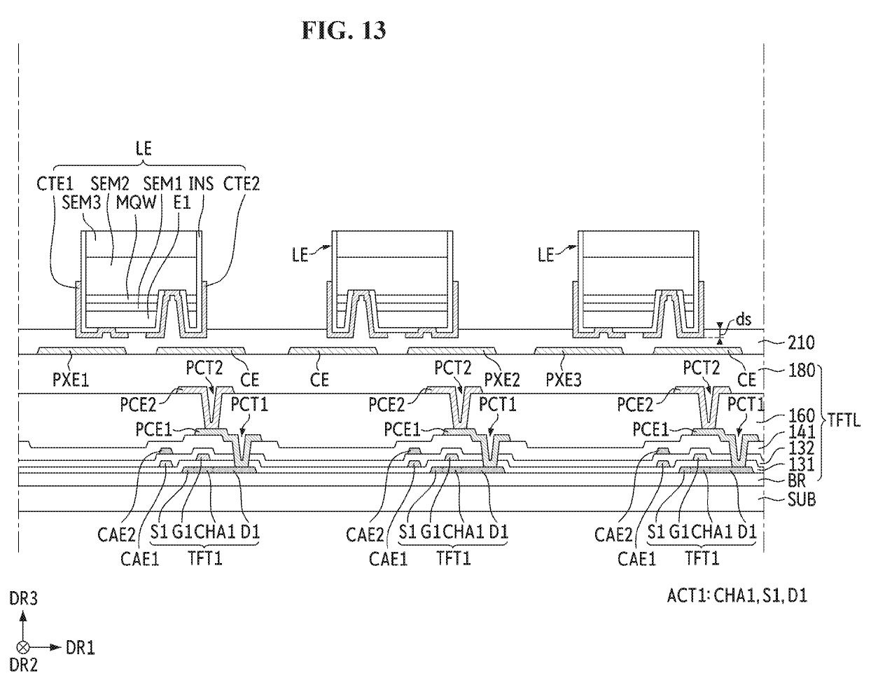

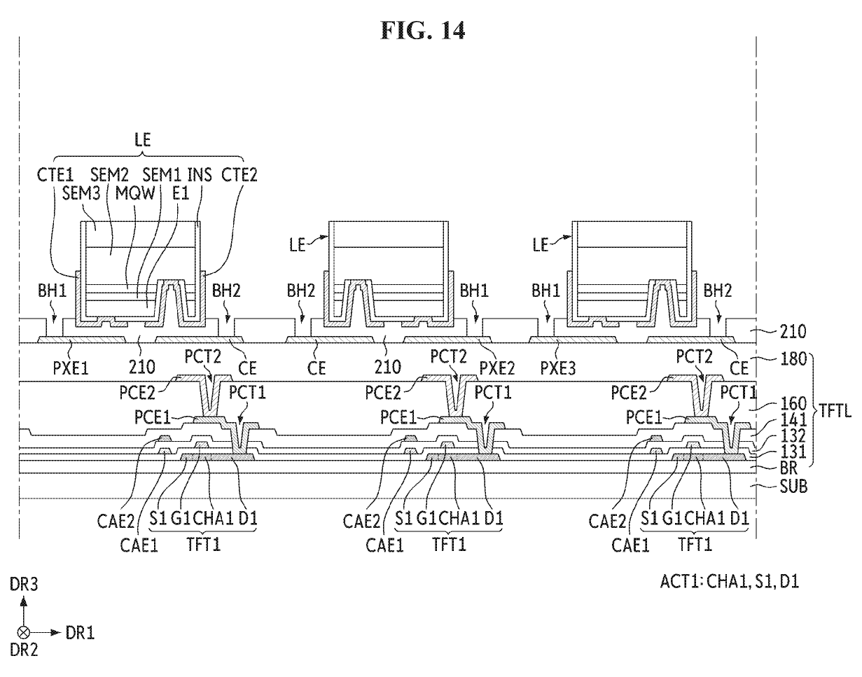

FIG. 8 is a flow chart illustrating a method for manufacturing a display device according to one or more embodiments. FIGS. 9 - 18 are example drawings to illustrate a method for manufacturing a display device according to one or more embodiments.

Hereinafter, a method for manufacturing a display device according to one or more embodiments will be described in detail by connecting FIG. 8 with FIGS. 9 – 20. In FIGS. 9 – 18, cross sections corresponding to the line I-I’ of FIG. 5 are illustrated for convenience of explanation.

First, as shown in FIG. 9, a second semiconductor material layer SEML2, an active material layer MQWL, a first semiconductor material layer SEML1, and a conductive material layer EL1 are formed on a semiconductor substrate SSUB. (S110 in FIG. 8). In one or more embodiments, a third semiconductor material layer SEML3 may be formed on the semiconductor substrate SSUB before forming the second semiconductor material layer SEML2.

The semiconductor substrate SSUB may be a silicon wafer substrate or a sapphire substrate.

A plurality of semiconductor material layers are formed on the semiconductor substrate SSUB. For example, a third semiconductor material layer SEML3 is formed on the semiconductor substrate SSUB. The third semiconductor material layer SEML3 may be an undoped semiconductor layer.

Then, a second semiconductor material layer SEML2 is formed on the third semiconductor material layer SEML3. The second semiconductor material layer SEML2 may be a semiconductor material layer doped with a second conductive dopant such as silicon (Si), germanium (Ge), or tin (Sn).

Then, an active material layer MQWL is formed on the second semiconductor material layer SEML2, and a first semiconductor material layer SEML1 is formed on the active material layer MQWL. The active material layer MQWL may include the same semiconductor material layer as the first semiconductor material layer SEML1 and the second semiconductor material layer SEML2. For example, when the first semiconductor material layer SEML1 and the second semiconductor material layer SEML2 include gallium nitride (GaN), the active material layer MQWL may also include gallium nitride (GaN). For example, the active material layer MQWL may include at least one of gallium nitride (GaN), indium gallium nitride (InGaN), or aluminum gallium nitride (AlGaN). The first semiconductor material layer SEML1 may be a semiconductor material layer doped with a first conductive dopant, such as magnesium (Mg), zinc (Zn), calcium (Ca), strontium (Sr), barium (Ba), and/or the like.

The third semiconductor material layer SEML3, the second semiconductor material layer SEML2, the active material layer MQWL, and the first semiconductor material layer SEML1 may be formed on a semiconductor substrate SSUB through an epitaxial growth process. As an epitaxial growth process, a method for forming the light extraction pattern layer, third semiconductor material layer SEML3, the second semiconductor material layer SEML2, the active material layer MQWL, and the first semiconductor material layer SEML1 may be used, such as an electron beam deposition method, a physical vapor deposition (PVD), a chemical vapor deposition (CVD), a plasma laser deposition (PLD), a dual-type thermal evaporation method, sputtering, a metal organic chemical vapor deposition (MOCVD), etc. Preferably, metal organic chemical vapor deposition (MOCVD) may be used, but the present disclosure is not limited thereto.

Then, a conductive material layer EL1 is formed on the first semiconductor material layer SEML1. The conductive material layer EL1 may be formed of molybdenum (Mo), aluminum (Al), chromium (Cr), gold (Au), titanium (Ti), nickel (Ni), neodymium (Nd), and/or copper (Cu).

Second, as shown in FIG. 10, the second semiconductor material layer SEML2, the active material layer MQWL, the first semiconductor material layer SEML1, and the conductive material layer EL1 are etched to form light emitting elements LE. (S120 in FIG. 8)

Referring to FIGS. 9 and 10, after forming a mask pattern on the conductive material layer EL1, the second semiconductor material layer SEML2, the active material layer MQWL, the first semiconductor material layer SEML1, and the conductive material layer EL1 are etched according to the mask pattern. The mask pattern may be removed after forming the light emitting elements LE.

The second semiconductor material layer SEML2, the active material layer MQWL, the first semiconductor material layer SEML1, and the conductive material layer EL1 may be etched by a dry etching method, a wet etching method, a reactive ion etching (RIE), a deep reactive ion etching (DRIE), an inductively coupled plasma reactive ion etching (ICP-RIE), etc. In the case of the dry etching method, anisotropic etching is possible and thus may be suitable for vertical etching. When the dry etching method is used, the etching gas may be, but is not limited to, chlorine (Cl₂) and/or oxygen (O₂) gas.

Then, a hole LEH is formed in each of the light emitting elements LE to expose the second semiconductor layer SEM2 by penetrating the conductive layer E1, the first semiconductor layer SEM1, and the active layer MQW.

Third, as shown in FIGS. 11 and 12, a protective film INS surrounding the light emitting elements LE is formed and contact electrodes CTE1 and CTE2 are formed. (S130 in FIG. 8)

In one or more embodiments, a protective material layer is entirely deposited on one surface of the semiconductor substrate SSUB. The protective material layer may be formed to cover one surface and side surfaces of the light emitting elements LE. The protective material layer may be formed on one surface of the semiconductor substrate SSUB exposed between the light emitting elements LE.

Then, a mask pattern is formed to expose a portion of the hole LEH of each of the light emitting elements LE. For example, the mask pattern may be formed so as not to cover the protective material layer arranged on the bottom surface of the hole LEH of each of the light emitting elements LE. Further, the first mask pattern may be arranged to expose a portion of the protective material layer arranged on one side of each of the light emitting elements LE.

Next, the protective material layer not covered by the mask pattern is etched. The protective material layer not covered by the mask pattern may be etched by dry etching. The protective material layer arranged on one side of each of the light emitting elements LE is etched, and thus the conductive layer E1 may be exposed without being covered by the protective material layer. Additionally, the protective material layer arranged between the light emitting elements LE is etched, and thus the semiconductor substrate SSUB may be exposed.

In addition, when a large upper and lower voltage difference is formed in the dry etching and the protective material layer is etched, the etching gas proceeds in the third direction DR3 and etches the protective material layer. As a result, the protective material layer arranged on the sidewall of the hole LEH of each of the light emitting elements LE may remain without being etched, even if it is not protected by the first mask pattern. Therefore, the protective material layer arranged on the bottom surface of the hole LEH of each of the light emitting elements LE is etched, and the second semiconductor layer SEM2 in the hole LEH of each of the light emitting elements LE may be exposed without being covered by the protective material layer.

Then, the mask pattern may be removed by an ashing process.

Thereafter, as shown in FIG. 11, an insulating film FL is filled between a portion of one surface of each of the light emitting elements LE and the light emitting elements LE. The thickness T of the insulating film FL arranged on one surface of each of the light emitting elements LE may be about 50% of the height h-LE of the light emitting element LE.

Then, a contact electrode layer is completely deposited on one surface of the semiconductor substrate SSUB. The contact electrode layer may be formed to cover one surface and side surfaces of the light emitting elements LE. The contact electrode layer may be arranged to cover the insulating film FL. The contact electrode layer may be formed on one surface of the semiconductor substrate SSUB exposed between the light emitting elements LE.

Thereafter, the insulating film FL is removed by a lift-off process, and the first contact electrodes CTE1 and the second contact electrodes CTE2 are formed.

As shown in FIG. 12, the first contact electrode CTE1 and the second contact electrode CTE2 may be exposed without covering the protective film INS arranged on the side surface of the third semiconductor layer SEML3. The height d-2 of the first contact electrodes CTE1 and the second contact electrode CTE2 may be about 50% of the height h-LE of the light emitting element LE.

Referring to FIGS. 11 and 12, because the first contact electrodes CTE1 and the second contact electrodes CTE2 are not formed where the insulating film FL is arranged, the thicker the insulating film FL (T in FIG. 11), the shorter the first contact electrodes CTE1 and the second contact electrodes CTE2. In other words, the height d-2 of the first contact electrodes CTE1 and the second contact electrodes CTE2 decreases.

The insulating film FL may be formed with a negative photoresist to remove the insulating film FL by the lift-off process. In this case, only the insulating film FL and the contact electrode layer arranged on the insulating film FL may be removed by a solvent ashing process using alcohol.

The insulating film FL may be partially arranged on one side of the light emitting element LE to form the first contact electrode CTE1 connected to the conductive layer E1 and the second contact electrode CTE2 connected to the second semiconductor layer SEM2 in a separated arrangement. Thus, the first contact electrode CTE1 and the second contact electrode CTE2 may be electrically separated from each other.

Fourth, as shown in FIG. 13, the light emitting elements LE are transferred to the first organic layer 210 arranged on the pixel electrodes PXE, and the semiconductor substrate SSUB is removed. (S140 in FIG. 8)

The light emitting elements LE may be transferred onto the first organic layer 210 arranged on the pixel electrodes PXE. At this time, the light emitting elements LE may be temporarily fixed by being embedded in the first organic layer 210. The first organic layer 210 may be formed on a substrate on which the pixel electrode PXE and the common electrode CE are formed by a coating process.

At least a portion of the first contact electrode CTE1 and the second contact electrode CTE2 of each of the light emitting elements LE may be embedded in the first organic layer 210.

Alternatively, the first organic layer 210 may be formed on the side surfaces of the conductive layer E1 of each of the light emitting elements LE. Alternatively, the first organic layer 210 may be arranged on the side surfaces of the first semiconductor layer SEM1, the side surfaces of the active layer MQW, and the side surfaces of the second semiconductor layer SEM2 of each of the light emitting elements LE. In this case, the first organic layer 210 may be arranged on a portion of each of the side surfaces of the second semiconductor layer SEM2.

The first contact electrode CTE1 and the second contact electrode CTE2 arranged on the side surfaces of the light emitting elements LE may be arranged within the first organic layer 210 by approximately 10% or more and approximately 60%.

If the first organic layer 210 has low flowability or is rigid, the depth at which the light emitting element LE is inserted or embedded in the first organic layer 210 may be very small (the depth ds) of the first contact electrode CTE1 and the second contact electrode CTE2 embedded in the first organic layer 210 is less than 10% of the total), or the light emitting element LE may be arranged on the first organic layer 210 without being inserted or embedded in the first organic layer 210.

Therefore, the first organic layer 210 includes a photo initiator and a fluidic monomer. To secure the depth at which the light emitting element LE is embedded in the first organic layer 210, the content of the photo initiator in the first organic layer 210 may be lowered or the content of the fluidic monomer may be increased. In this way, the degree of hardness of the material of the first organic layer 210 may be controlled to increase the adhesion and deformation rate (e.g., flowability) of the first organic layer 210. As a result, the depth at which the light emitting element LE is inserted or embedded in the first organic layer 210 may be controlled (e.g., the depth ds of the first contact electrode CTE1 and the second contact electrode CTE2 embedded in the first organic layer 210, which is between 10% and 60% of the total the height of the first contact electrode CTE1 and the second contact electrode CTE2).

Generally, when the curing rate of the first organic layer 210 increases, the pressing depth of the light emitting element LE decreases, which may lower the bonding rate, and as the viscosity of the first organic layer 210 increases, the hardness may decrease. The pressing depth of the light emitting element LE may be the depth ds at which the first contact electrode CTE1 and the second contact electrode CTE2 described above are embedded in the first organic layer 210.

For example, in one or more embodiments, after the first organic layer 210 is cured (soft baked) at a first temperature, at least a portion of each of the plurality of light emitting elements LE is inserted into the first organic layer 210. Then, the first organic layer 210 may be completely cured at a second temperature higher than the first temperature. The first temperature may be approximately 100 degrees, and the second temperature may be approximately 230 degrees, but the present disclosure is not limited thereto. Further, the process of completely curing the first organic layer 210 at the second temperature may be performed for approximately 30 minutes.

Then, the semiconductor substrate SSUB is removed by a laser lift-off process. Alternatively, when the light emitting elements LE are transferred to a separate transfer substrate instead of the semiconductor substrate SSUB, the transfer substrate may be removed instead of the semiconductor substrate SSUB.

Fifth, as shown in FIGS. 14 – 17, first connection electrodes BE1 and second connection electrodes BE2 are formed. (S150 in FIG. 8)

In one or more embodiments, as shown in FIG. 14, a first connection hole BH1 that penetrates the first organic layer 210 and exposes at least a portion of the pixel electrodes PXE1, PXE2, and PXE3 and a second connection hole BH2 that penetrates the first organic layer 210 and exposes at least a portion of the common electrodes CE1, CE2, and CE3 are formed.

Then, as shown in FIG. 15, a bonding electrode layer BEL is deposited on the entire surface of the circuit substrate SUB. The bonding electrode layer BEL may be formed to cover one surface and side surfaces of the light emitting elements LE.

Then, a mask pattern PR that covers the first connection hole BH1 and the second connection hole BH2 from a portion of the side surface of the light emitting element LE is formed.

Afterwards, as shown in FIG. 17, the first connection electrodes BE1 and the second connection electrodes BE2 are formed by a photo process of etching the bonding electrode layer BEL that is not covered by the mask pattern PR.

The first connection electrodes BE1 connect the first contact electrode CTE1 of the light emitting element LE and the pixel electrode PXE exposed by the first connection hole BH1, and the second connection electrodes BE2 connect the second contact electrode CTE2 of the light emitting element LE and the common electrode CE exposed by the second connection hole BH2.

Sixth, as shown in FIG. 18, the second organic layer 211, the third organic layer 212, the capping layer CAP, the fourth organic layer 213, the color filter CF1, CF2, and CF3, and the fifth organic layer 214 are formed sequentially. (S160 in FIG. 8)

The second organic layer 211 and the third organic layer 212 are formed to fix the light emitting elements LE and to flatten the step caused by the light emitting elements LE.

The capping layer CPL is formed on the third organic layer 212 and the light emitting elements LE, and the fourth organic layer 213 is formed on the capping layer CPL.

Then, the first color filter CF1 is formed on the first sub-pixel SPX1, the second color filter CF2 is formed on the second sub-pixel SPX2, and the third color filter CF3 is formed on the third sub-pixel SPX3 in the third direction DR3 on the fourth organic layer 213. The edges of the first color filter CF1, the second color filter CF2, and the third color filter CF3 may overlap each other to form a light blocking layer.

Then, the fifth organic layer 214 is formed on the first color filter CF1, the second color filter CF2, and the third color filter CF3.

FIG. 19 is a perspective view to illustrate an air gap (or air pocket) according to a bonding state of a conventional light emitting element and a first organic layer.

Referring to FIG. 19, when the light emitting element LE is arranged on the first organic layer 210 without being embedded, a gap (or air pocket) AP may be formed between the first contact electrode CTE1 and the second contact electrode CTE2.

When the first organic layer 210 is formed to cover the pixel electrode PXE1 and the common electrode CE, the first organic layer 210 may be formed lower in an area where the pixel electrode PXE1 and the common electrode CE are not arranged than in an area where the pixel electrode PXE1 and the common electrode CE are arranged, because the area between the first contact electrode CTE1 and the second contact electrode CTE2 of the light emitting element LE overlaps with the area where the pixel electrode PXE1 and the common electrode CE are not arranged.

When a gap (or air pocket) AP is formed between the first contact electrode CTE1 and the second contact electrode CTE2, the etchant may seep into the gap during the process of forming the connection electrodes BE1 and BE2, causing a short circuit of the connection electrodes BE1 and BE2.

On the other hand, as in one or more embodiments, when the light emitting element LE is deeply embedded in the first organic layer 210, the first organic layer 210 is filled between the first contact electrode CTE1 and the second contact electrode CTE2, so that a gap is not formed, thereby solving the above problem.

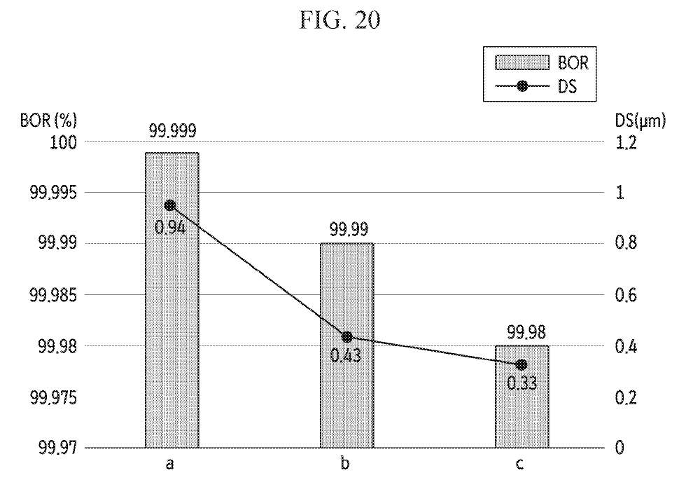

FIG. 20 is a graph to illustrate a bonding characteristic according to a process of the first organic layer according to one or more embodiments.

As described above, to increase the depth of the light emitting element LE, one method involves adjusting the content of photoinitiator and the fluidic monomer of the first organic layer 210. Another method may be a method of changing the process.

When the first organic layer 210 is a photosensitive organic film such as a photoresist, the bonding rate (or adhesion rate) decreases during the coating process, the photo process, and the developing process. When the bonding rate (or adhesion rate) of the first organic layer 210 decreases, a pressing depth DS of the light emitting element LE decreases. The coating process is a process of uniformly applying a photosensitive organic film, and the photolithography process is a process of exposing the photosensitive organic film to light or radiation to induce a reaction. The development process is a process of removing a portion of the photosensitive organic film using a developer, etc.

Referring to FIG. 20, the bonding rate BOR and pressing depth DS according to the process of the first organic layer (210 in FIG. 7) are shown.

In the graph, a horizontal axis represents (a) the coating process, (b) the photo process, (c) the development process, and BOR vertically represents the bonding rate, and DS represents the pressing depth DS of the light emitting element LE.

The bonding rate BOR of the first organic layer 210 after the coating process (a) is 99.999% and the pressing depth DS of the light emitting element LE is 0.94μm. Then, the bonding rate BOR of the first organic layer 210 after the photo process (b) is 99.99% and the pressing depth DS of the light emitting element LE is 0.43μm. Thereafter, the bonding rate BOR of the first organic layer 210 after the development process (c) is 99.98% and the pressing depth DS of the light emitting element LE is 0.33μm.

As such, as the coating process (a), the photo process (b), and the development process (c) are performed, the bonding rate BOR of the first organic layer 210 decreases, and the pressing depth DS of the light emitting element LE also decreases.

In one or more embodiments, the coating process and the photo process of the first organic layer 210 are performed, but the developing process is not performed, so the pressing depth DS of the light emitting element LE may be secured. The pressing depth DS of the light emitting element LE may be set to be between 5% and 30% of the total height of the light emitting element LE or between approximately 10% and 60% of the first contact electrode CTE1 and second contact electrode CTE2 of the light emitting element LE.

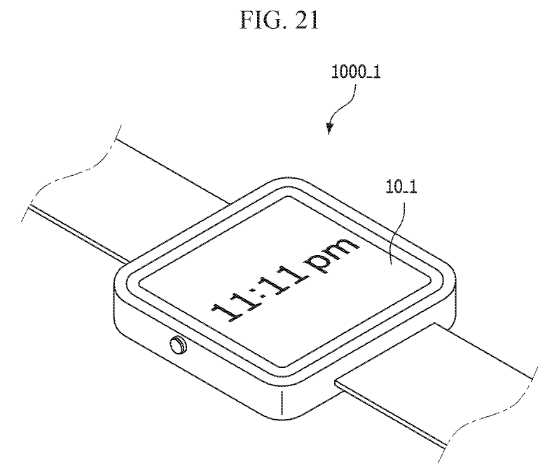

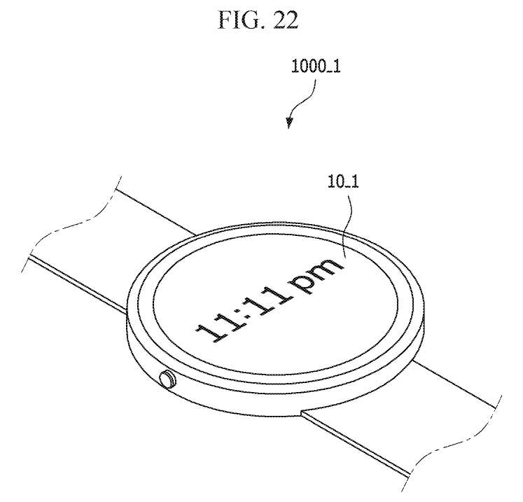

FIGS. 21 and 22 are example drawings illustrating a smart watch including a display device according to one or more embodiments.

Referring to FIGS. 21 and 22, a display device 10_1 according to one or more embodiments may be applied to a smart watch 1000_1, which is one of smart devices.

The flat shape of the display device 10_1 may be a square or a circle but is not limited thereto and may be modified in various ways, such as an oval.

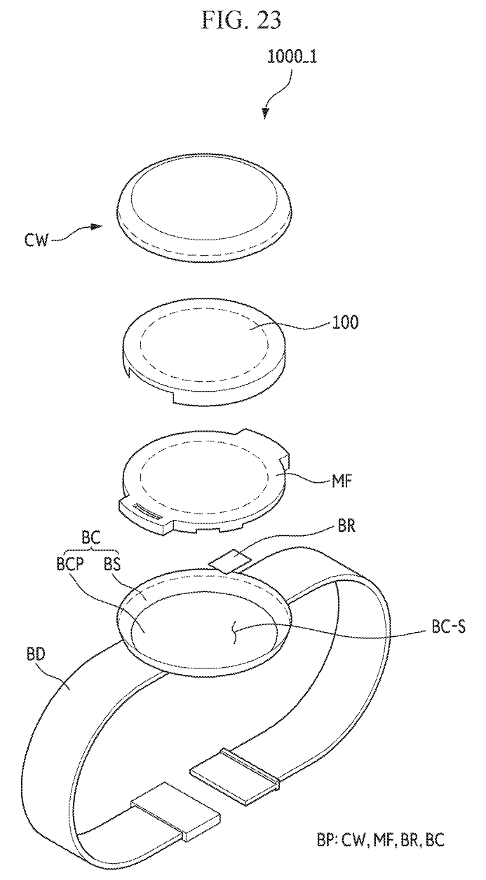

FIG. 23 is an exploded perspective view of a smart watch including a display device according to one or more embodiments.

Referring to FIG. 23, the smart watch 1000_1 may include a main body unit BP and a wearable portion BD.

The main body unit BP may include a display panel 100 on which an image is displayed, a cover window CW disposed on the display panel 100, a bottom cover BC disposed under the display panel 100, a middle frame MF disposed between the cover window CW and the bottom cover BC, and a battery BR disposed between the middle frame MF and the bottom cover BC. In addition to the battery BR, a main processor controlling the smart watch 1000_1, a communication chipset for wirelessly communicating with the outside, and a circuit board in which memory, etc. are mounted may be additionally arranged between the middle frame MF and the bottom cover BC.

The main body unit BP may sequentially include a bottom cover BC, a battery BR, a middle frame MF, a display panel 100, and a cover window CW.

The cover window CW is arranged on the upper portion of the display panel 10 to protect the display panel 10 and to transmit light emitted from the display panel 10. As described above, the cover window CW may include a light-blocking portion to block a portion of the light emitted from the display panel 10. The cover window CW may be made of a transparent plastic material, a glass material, or a reinforced glass material.

The cover window CW may be arranged to overlap the display panel 100 and cover the front of the display panel 100. The cover window CW generally has a shape similar to that of the display panel 100 in terms of a plane, but its size may be larger than that of the display panel 100. For example, the cover window CW may protrude outward from the display panel 100. The plane shape of the cover window CW may be the same as that of the main body unit BP. For example, the planar shape of the cover window CW may be generally circular but is not limited thereto and may have various shapes, for example, a polygon such as a square or an oval.

The middle frame MF is a joining member for joining the cover window CW and the bottom cover BC and is arranged between the cover window CW and the bottom cover BC. For example, the middle frame MF may include a bracket.

The bottom cover BC is a housing arranged under the display panel 10.

The bottom cover BC may include a central cover portion BCP and a peripheral portion BS arranged around the central cover portion BCP.

The central cover portion BCP is located at the center of the bottom cover BC and may be generally flat.

The peripheral portion BS may be arranged to be around (e.g., to surround) the central cover portion BCP. The peripheral portion BS may be a portion that is bent and curved from the central cover portion BCP. The peripheral portion BS may be bent from the edge of the central cover portion BCP. In some embodiments, the peripheral portion BS may include a curved surface having a suitable curvature (e.g., a predetermined curvature), and the other portion may be flat. The degree (or angle) at which the peripheral portion BS is bent from the central cover portion BCP may be an obtuse angle, but is not limited thereto, and may also be a right angle or an acute angle.

A storage space BC-S may be formed by the central cover portion BCP and the peripheral portion BS. A battery BR may be placed in the storage space BC-S.

The battery BR may be connected to a circuit board on which a main processor or the like is mounted. The display device 10_1 may be electrically connected to the circuit board to receive digital video signals, timing signals, power, and the like.

The bottom cover BC is placed on the outermost rear surface of the electronic device and may include at least one of a plastic material, a metal material, and a glass material, and may include a color coating layer. For example, the bottom cover BC according to one example may be a flat glass having a transparent, translucent, or opaque color coating layer.

The bottom cover BC according to another example may have the same shape as the cover window CW and may include a glass material having a color coating layer. For example, the bottom cover BC according to another example may have a structure symmetrical to the cover window CW with a middle frame MF in between and may include a transparent, translucent, or opaque color coating layer.

The wearing portion BD is a portion for fixing the main body unit BP to the user’s wrist, for example, and may be one of a strap, a chain, and a bracelet.

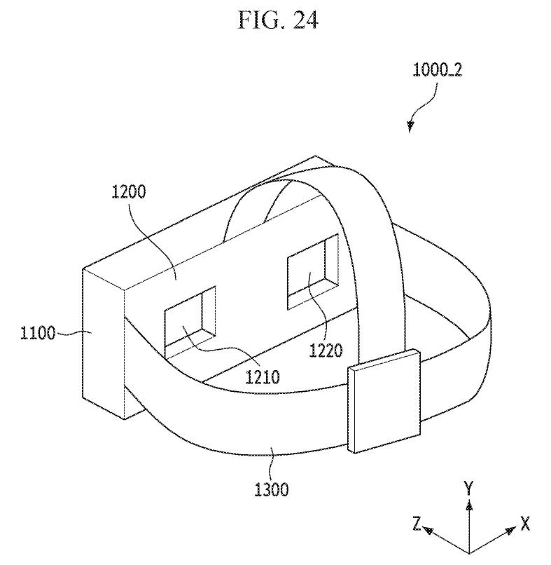

FIG. 24 is example views of a virtual reality (VR) device including a display device according to one or more embodiments.

Referring to FIG. 24, a head mounted display device 1000_2 according to one or more embodiments includes a display device housing 1100, a housing cover 1200, a first eyepiece 1210, a second eyepiece 1220, and head mounted band 1300.

The display device housing 1100 houses a display device. A head mounted display device 1000_2 according to one or more embodiments further include a first optical member disposed between the first display device and the first eyepiece 1210.

The housing cover 1200 is placed to cover an open surface of the display device housing 1100. The housing cover 1200 may include the first eyepiece 1210 on which a user’s left eye is placed and the second eyepiece 1220 on which the user’s right eye is placed. Although the first eyepiece 1210 and the second eyepiece 1220 are disposed separately in FIGS. 24, the present disclosure is not limited thereto. The first eyepiece 1210 and the second eyepiece 1220 may also be combined into one.

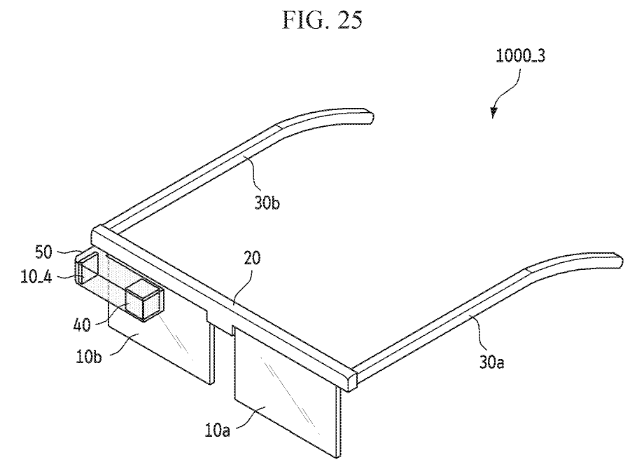

The head mounted band 1300 fixes the display device housing 1100 to a user’s head so that the first eyepiece 1210 and the second eyepiece 1220 of the housing cover 1200 are kept placed on the user’s left and right eyes, respectively. When the display device housing 1200 is implemented to be lightweight and small, the head mounted display device 1000_2 may include an eyeglass frame as illustrated in FIG. 25 instead of the head mounted band 1300.

The display device housing 1100 houses display device. In addition, the head mounted display device 1000_2 may further include a battery for supplying power, an external memory slot for accommodating an external memory, and an external connection port and a wireless communication module for receiving an image source. The external connection port may be a universe serial bus (USB) terminal, a display port, or a high-definition multimedia interface (HDMI) terminal, and the wireless communication module may be a 5G communication module, a 4G communication module, a Wi-Fi module, and/or a Bluetooth module.

FIG. 25 is an example view of a VR device including a display device according to one or more embodiments. FIG. 25 illustrates a VR device 1000_3 to which a display device 10_4 according to one or more embodiments has been applied.

Referring to FIG. 25, the VR device 1000_3 according to one or more embodiments may be a device in the form of glasses. The VR device 1000_3 according to the embodiment may include the display device 10_4, a left lens 10a, a right lens 10b, a support frame 20, eyeglass frame legs 30a and 30b, a reflective member 40, and a display device housing 50.

In FIG. 25, a case where the VR device 1000_3 is a glasses-type display device including the eyeglass frame legs 30a and 30b is illustrated as an example. That is, the VR device 1000_3 according to the embodiment is not limited to the one illustrated in FIG. 31 and can be applied in various forms to various other electronic devices.

The display device housing 50 may include the display device 10_4 and the reflective member 40. An image displayed on the display device 10_4 may be reflected by the reflective member 40 and provided to a user’s right eye through the right lens 10b. Accordingly, the user may view a VR image displayed on the display device 10_4 through the right eye.

Although the display device housing 50 is disposed at a right end of the support frame 20 in FIG. 25, the present disclosure is not limited thereto. For example, the display device housing 50 may also be disposed at a left end of the support frame 20. In this case, an image displayed on the display device 10_4 may be reflected by the reflective member 40 and provided to the user’s left eye through the left lens 10a. Accordingly, the user may view a VR image displayed on the display device 10_4 through the left eye. Alternatively, the display device housing 50 may be disposed at both the right end and the left end of the support frame 20. In this case, the user may view a VR image displayed on the display device 10_4 through both the left eye and the right eye.

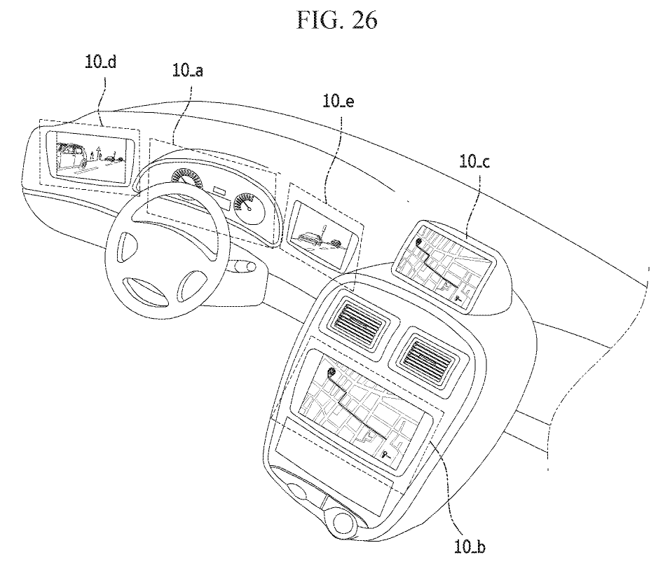

FIG. 26 is an example view illustrating a vehicle instrument cluster and center fascia including display devices according to one or more embodiments. FIG. 26 illustrates a vehicle to which display devices 10_a through 10_e according to one or more embodiments have been applied.

Referring to FIG. 26, the display devices 10_a through 10_c according to the embodiment may be applied to an instrument cluster of the vehicle, a center fascia of the vehicle, or a center information display (CID) disposed on a dashboard of the vehicle. In addition, the display devices 10_d and 10_e according to the embodiment may be applied to room mirror displays that replace side mirrors of the vehicle.

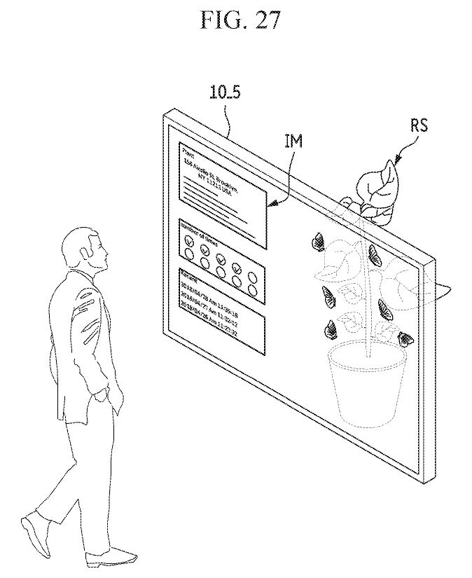

FIG. 27 is an example view of a transparent display device including a display device according to one or more embodiments.

Referring to FIG. 27, a display device 10_5 according to one or more embodiments may be applied to a transparent display device. The transparent display device may transmit light while displaying an image IM. Therefore, a user located in front of the transparent display device cannot only view the image IM displayed on the display device 10_5 but also view an object RS or the background located behind the transparent display device. When the display device 10_5 is applied to the transparent display device, a substrate of the display device 10_5 may include a light transmitting portion that can transmit light or may be made of a material that can transmit light.

It should be understood, however, that the aspects and features of embodiments of the present disclosure are not restricted to the one set forth herein. The above and other aspects of the present disclosure will become more apparent to one of ordinary skill in the art to which the present disclosure pertains by referencing the claims, with equivalents thereof to be included therein.

What is claimed is:

1. A display device comprising:
a substrate;
a pixel electrode and a common electrode spaced from each other on the substrate;
a first organic layer covering at least a portion of the pixel electrode and the common electrode; and
a light emitting element on the first organic layer, the light emitting element comprising a plurality of semiconductor layers, a first contact electrode, and a second contact electrode,
wherein the first contact electrode and the second contact electrode are respectively located on one surface and a side surface of the light emitting element, and are spaced from a top surface of the light emitting element, and
wherein 10% or more and 60% or less of the first contact electrode and the second contact electrode located on the side surface of the light emitting element are embedded in the first organic layer.

2. The display device of claim 1, wherein the first organic layer covers 5% or more and 30% or less of the side surface of the light emitting element.

3. The display device of claim 1, wherein each of a height of the first contact electrode and the second contact electrode located on the side surface of the light emitting element is 50% of the height of the light emitting element.

4. The display device of claim 1, wherein the first organic layer is on an entire surface of the substrate and covers the side surface of the light emitting element.

5. The display device of claim 4, wherein the first organic layer covers the pixel electrode and the common electrode and includes a first connection hole exposing a portion of the pixel electrode, a second connection hole exposing a portion of the common electrode, and
wherein the display device further comprises a first connection electrode and a second connection electrode, the first connection electrode connecting the pixel electrode and the first contact electrode through the first connection hole, and the second connection electrode connecting the common electrode and the second contact electrode through the second connection hole.

6. The display device of claim 5, wherein the first contact electrode is in direct contact with the first connection electrode at a side of the plurality of semiconductor layers, and wherein the second contact electrode is in direct contact with the second connection electrode at the side of the plurality of semiconductor layers.

7. The display device of claim 1, wherein a groove formed by a thickness of the first contact electrode and the second contact electrode is on one side of the light emitting element, and
wherein the groove is filled with the first organic layer.

8. The display device of claim 1, wherein the light emitting element further comprises:
a conductive layer on one surface of the plurality of semiconductor layers; and
a protective film on one surface and side surfaces of the conductive layer and side surfaces of the plurality of semiconductor layers,
wherein the first contact electrode is on the protective film and is connected to the conductive layer exposed without being covered by the protective film, and
wherein the second contact electrode is on the protective film and is in a hole penetrating the conductive layer and a portion of the plurality of semiconductor layers.

9. The display device of claim 8,
wherein the hole is filled with the first organic layer.

10. A method for manufacturing a display device comprising:
forming light emitting elements, a light emitting element of the light emitting elements comprising a plurality of semiconductor layers on a semiconductor substrate;
forming a protective layer of the light emitting element and a first contact electrode and a second contact electrode covering one side and a side surface of the light emitting element;
transferring the light emitting element onto a first organic layer coated on an entire surface of a circuit substrate covering a pixel electrode and a common electrode on the circuit substrate; and
forming a first connection electrode connecting the pixel electrode and the first contact electrode and a second connection electrode connecting the common electrode and the second contact electrode by a photo process,
wherein 10% or more and 60% or less of the first contact electrode and the second contact electrode on the side surface of the light emitting element are embedded in the first organic layer.

11. The method of claim 10, wherein the first organic layer covers 5% or more and 30% or less of the side surface of the light emitting element.

12. The method of claim 10, wherein the forming the protective layer of the light emitting element and the first contact electrode and the second contact electrode covering the one side and the side surface of the light emitting element comprises:
forming a protective material layer around each of the light emitting elements and patterning the protective material layer to form a protective film;
forming an insulating layer on the protective film covering 50% of height of the light emitting element and forming a contact electrode layer; and
removing the insulating layer to form the first contact electrode and the second contact electrode in each of the light emitting elements,
wherein heights of the first contact electrode and the second contact electrode are 50% of the height of the light emitting element.

13. The method of claim 10, further comprising:
forming a first connection hole in the first organic layer exposing a portion of the pixel electrode and a second connection hole exposing a portion of the common electrode,
wherein the first connection electrode connects the pixel electrode and the first contact electrode through the first connection hole, and
wherein the second connection electrode connects the common electrode and the second contact electrode through the second connection hole.

14. The method of claim 13, wherein the first connection electrode is connected to a portion of the first contact electrode that is not embedded in the first organic layer, and wherein the second connection electrode is connected to a portion of the second contact electrode that is not embedded in the first organic layer.

15. The method of claim 10, wherein the forming the light emitting elements comprising the plurality of semiconductor layers on the semiconductor substrate further comprises:
forming a second semiconductor material layer, an active material layer, a first semiconductor material layer, and a conductive material layer on the semiconductor substrate;
etching the second semiconductor material layer, the active material layer, the first semiconductor material layer, and the conductive material layer to form light emitting elements comprising a second semiconductor layer, an active layer, a first semiconductor layer, and a conductive layer, respectively; and
forming a hole penetrating the conductive layer, the first semiconductor layer, and the active layer in each of the light emitting elements,
wherein the first contact electrode is connected to the conductive layer, and the second contact electrode is connected to the second semiconductor layer in the hole.

16. The method of claim 15, wherein the hole is filled with the first organic layer.

17. The method of claim 10, wherein a groove formed by a thickness of the first contact electrode and the second contact electrode is formed on one side of the light emitting element, and
wherein the groove is filled with the first organic layer.

18. The method of claim 10,
wherein the first organic layer is controlled by lowering a content of a photoinitiator in the first organic layer or increasing a content of a fluidic monomer so that the first organic layer covers 10% or more and 60% or less of the first contact electrode and the second contact electrode located on side of the light emitting element.

19. An electronic device comprising:
a display panel;
a window on the display panel; and
a bottom cover located below the display panel,
wherein the display panel comprises:
a substrate;
a pixel electrode and a common electrode spaced from each other on the substrate;
a first organic layer covering at least a portion of the pixel electrode and the common electrode; and
a light emitting element on the first organic layer, the light emitting element comprising a plurality of semiconductor layers, a first contact electrode, and a second contact electrode,
wherein the first contact electrode and the second contact electrode are respectively located on one surface and a side surface of the light emitting element, and are spaced from a top surface of the light emitting element, and
wherein the first organic layer covers 10% or more and 60% or less of the first contact electrode and the second contact electrode located on the side surface of the light emitting element.

20. The electronic device of claim 19, further comprising a battery located in a space of the bottom cover and configured to supply power to the electronic device; and
a middle frame located between the window and the bottom cover.
